(19) United States
(12) Patent Application Publication
(10) Pub. No.: US 2026/0059977 A1
(43) Pub. Date: Feb. 26, 2026

(54) DISPLAY DEVICE AND ELECTRONIC DEVICE INCLUDING THE SAME

(71) Applicant: SAMSUNG DISPLAY CO., LTD., Yongin-si (KR)

(72) Inventors: JUNGKYU LEE, Yongin-si (KR); SUNGKOOK LEE, Yongin-si (KR)

(21) Appl. No.: 19/230,673

(22) Filed: Jun. 6, 2025

(30) Foreign Application Priority Data
Aug. 22, 2024 (KR) 10-2024-0112772

(51) Int. Cl. H10K 59/80; H10K 102/00

(52) U.S. Cl. CPC H10K 59/873; H10K 2102/311

(57) ABSTRACT

A display device includes an electronic panel including a folding portion and a non-folding portion arranged in a first direction, a window disposed on the electronic panel, an adhesive layer disposed between the electronic panel and the window, and a first protective layer disposed between the adhesive layer and the electronic panel. The folding portion includes a first side and a second side opposite to the first side in a second direction intersecting the first direction. The first protective layer is disposed adjacent to the first side of the folding portion.

### CROSS-REFERENCE TO RELATED APPLICATION(S)

This patent application claims priority under 35 U.S.C. § 119 to Korean Patent Application No. 10-2024-0112772, filed on Aug. 22, 2024 in the Korean Intellectual Property Office, the disclosure of which is incorporated by reference in its entirety herein.

### 1. Technical Field

The present disclosure is directed to a display device and an electronic device including the display device.

### 2. Description of Related Art

Electronic devices that provide images to a user, such as a smart phone, a digital camera, a notebook computer, a navigation unit, and a smart television, include a display device to display the images. The display device generates the images and provides them to a user via its display screen.

In recent years, advancements in display device technology have led to the development of various types of display devices. For example, flexible display devices, including foldable and rollable designs, are being introduced. These flexible display devices enhance portability and user convenience.

A foldable display device includes a folding portion and non-folding portions. The folding portion is the section of the display that bends when the device is folded or unfolded. This portion is made from flexible materials. The non-folding portions are rigid sections of the display that do not bend. These portions provide structural support to the device and house components such as display drivers and sensors.

Since the folding portion is flexible, the folding portion is easily damaged due to external impacts. Accordingly, it is necessary to develop a display device that includes a folding portion with enhanced resistance.

### SUMMARY

The present disclosure provides a display device including a folding portion with enhanced impact resistance and an electronic device including the display device.

An embodiment of the inventive concept provides a display device including an electronic panel including a folding portion and a non-folding portion arranged in a first direction, a window disposed on the electronic panel, an adhesive layer disposed between the electronic panel and the window, and a first protective layer disposed between the adhesive layer and the electronic panel. The folding portion includes a first side and a second side opposite to the first side in a second direction intersecting the first direction. The first protective layer is adjacent to the first side of the folding portion.

The display device may further include a second protective layer spaced apart from the first protective layer in the second direction and disposed adjacent to the second side between the adhesive layer and the electronic panel.

The first protective layer and the second protective layer may extend in the first direction.

In an embodiment, an edge of the first protective layer, which faces outward, is spaced apart from the first side, and an edge of the second protective layer, which faces outward, is spaced apart from the second side when viewed in a plane.

In an embodiment, the edge of the first protective layer, which faces outward, and the edge of the second protective layer, which faces outwards, respectively overlap both sides of the adhesive layer, which are opposite to each other in the second direction, when viewed in the plane.

The first protective layer and the second protective layer may extend to the non-folding portion adjacent to the folding portion.

In an embodiment, a width of the first protective layer in the second direction and a width of the second protective layer in second direction are each within a range from about 10% to about 15% of a of the electronic panel in the second direction.

Each of the first protective layer and the second protective layer may have a first thickness smaller than a second thickness of the adhesive layer in a third direction perpendicular to a plane defined by the first direction and the second direction.

The first thickness may be within a range from about 10% to about 15% of the second thickness.

The first protective layer and the second protective layer may be in contact with the adhesive layer and covered by the adhesive layer.

The first protective layer and the second protective layer may be in direct contact with an upper surface of the electronic panel.

In an embodiment, an edge of the first protective layer, which faces outward, extends to the first side and overlaps the first side, and an edge of the second protective layer, which faces outward, extends to the second side and overlaps the second side when viewed in the plane.

The first protective layer and the second protective layer may be integrally connected and extend along an edge of the electronic panel in a closed-loop shape.

The first protective layer may include first protective layers that extend in the first direction and are adjacent to the first side, and the second protective layer may include second protective layers that extend in the first direction and are adjacent to the second side

The first protective layer and the second protective layer may be integrally connected, extend along an edge of the folding portion, and further extend to a portion of the non-folding portion adjacent to the folding portion.

Each of the first protective layer and the second protective layer may be arranged as multiple dots on the electronic panel.

An embodiment of the inventive concept provides a display device including an electronic panel including a folding portion and a non-folding portion arranged in a first direction, a window disposed on the electronic panel, an adhesive layer disposed between the electronic panel and the window, a first protective layer adjacent to a first side of the folding portion, and a second protective layer adjacent to a second side of the folding portion opposite to the first side in a second direction intersecting the first direction. The first and second protective layers extend in the first direction and overlap opposite edges of the adhesive layer in the second direction.

Each of the protective layers may have a thickness smaller than a thickness of the adhesive layer in a third direction perpendicular to a plane defined by the first direction and the second direction.

In an embodiment, each of edges of the protective layers, which faces outward, extends to the first side to overlap the first side and extends to the second side to overlap the second side.

An embodiment of the inventive concept provides an electronic device including a display device having a first hole to transmit an optical signal, an electro-optical module disposed under the display device and overlapping the first hole for receiving the optical signal, and first and second cases accommodating the display device and the electro-optical module and enabling the display device to be folded. The display device includes an electronic panel including a folding portion and a non-folding portion arranged in a first direction, a window disposed on the electronic panel, an adhesive layer disposed between the electronic panel and the window, and a first protective layer disposed between the adhesive layer and the electronic panel. The folding portion includes a first side and a second side opposite to the first side in a second direction intersecting the first direction. The first protective layer is disposed adjacent to the first side of the folding portion.

According to at least one of the above embodiments, the first protective layer and the second protective layer are respectively disposed at both sides of the folding portion of the electronic panel, and thus, the thickness at the both sides of the folding portion of the electronic panel increases. As the thickness at the both sides of the folding portion of the electronic panel increases, the rigidity of the folding portion is enhanced, and thus, the folding portion is prevented from being damaged.

### BRIEF DESCRIPTION OF THE DRAWINGS

The above features of the present disclosure will become readily apparent by reference to the following detailed description when considered in conjunction with the accompanying drawings wherein:

FIG. 1 is a perspective view of an electronic device according to an embodiment of the present disclosure;

FIG. 2 is a perspective view of the electronic device shown in FIG. 1 in a folded state;

FIG. 3 is a perspective view of an electronic device according to an embodiment of the present disclosure;

FIG. 4 is a perspective view of the electronic device shown in FIG. 3 in a folded state;

FIG. 5 is an exploded perspective view of an electronic device according to an embodiment of the present disclosure;

FIG. 6 is a plan view of a display panel applied to the electronic device shown in FIG. 1;

FIG. 7 is a block diagram of the electronic device shown in FIG. 5;

FIG. 8 is a cross-sectional view of an electronic panel including a display panel shown in FIG. 5;

FIG. 9 is a cross-sectional view of a display panel shown in FIG. 8;

FIG. 10 is a cross-sectional view of an electronic panel corresponding to one pixel shown in FIG. 6;

FIG. 11 is a cross-sectional view taken along a line I-I′ shown in FIG. 6;

FIG. 12A is a cross-sectional view taken along a line II-II′ shown in FIG. 6;

FIG. 12B is a cross-sectional view of a bending area shown in FIG. 12A in a folded state;

FIG. 13 is a perspective view of a support plate shown in FIG. 11;

FIG. 14 is an enlarged plan view of an area AA shown in FIG. 13;

FIG. 15 is a view of a display device shown in FIG. 11 in a folded state;

FIG. 16 is a plan view of an electronic panel and protective layers disposed on the electronic panel shown in FIG. 11;

FIG. 17 is a cross-sectional view taken along a line III-III′ shown in FIG. 16; and

FIGS. 18 to 22 are plan views of electronic devices according to embodiments of the present disclosure.

FIG. 23 is an electronic device according to an embodiment of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, embodiments of the present disclosure will be described with reference to accompanying drawings.

Embodiments of the disclosure relate to a display device with a folding portion that enhances impact resistance and durability, particularly for foldable electronic devices. The display device includes a folding portion and non-folding portions, with protective layers strategically positioned to reinforce the structure and prevent damage caused by repeated folding and external impacts. These protective layers are placed adjacent to both sides of the folding portion and are located between an adhesive layer and an electronic panel, ensuring both flexibility and mechanical support. By increasing the thickness at the edges of the folding portion, the embodiment helps reduce stress concentration, which in turn minimizes the risk of cracks or deformation over time.

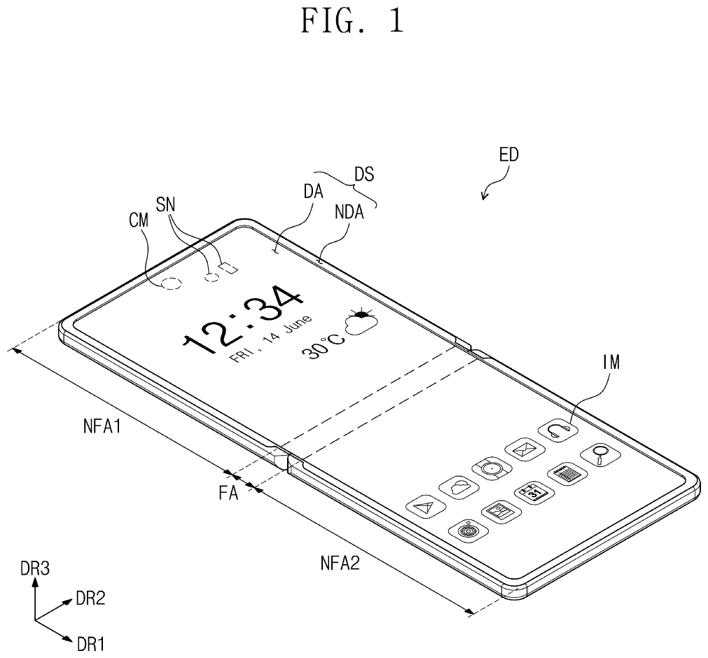

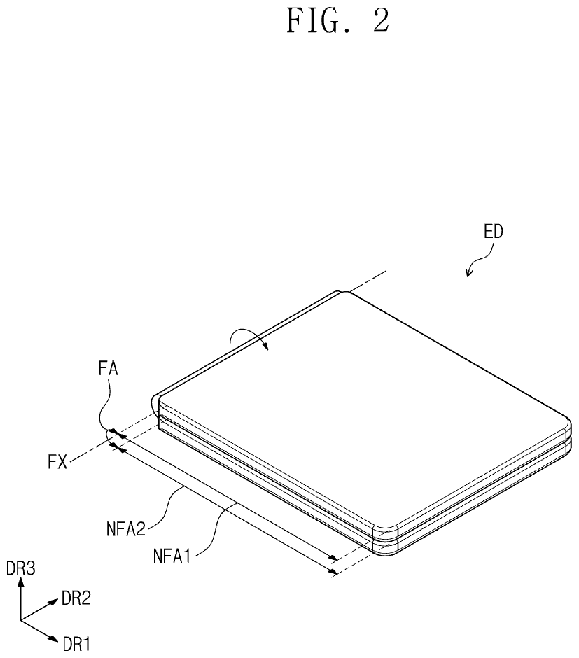

FIG. 1 is a perspective view of an electronic device ED according to an embodiment of the present disclosure. FIG. 2 is a perspective view of the electronic device ED shown in FIG. 1 in a folded state.

Referring to FIG. 1, the electronic device ED may have a rectangular shape defined by long sides extending in a first direction DR1 and short sides extending in a second direction DR2 intersecting the first direction DR1. However, the shape of the electronic device ED is not limited to the rectangular shape, and the electronic device ED may have various shapes, such as a circular shape and a polygonal shape. The electronic device ED may be a flexible display device.

Hereinafter, a direction substantially perpendicular to a plane defined by the first direction DR1 and the second direction DR2 may be referred to as a third direction DR3. In the present disclosure, the expression “when viewed in a plane” may mean a state of being viewed in the third direction DR3. In addition, the term “overlap” may refer to a state in which components are arranged to overlap each other when viewed in the plane.

The electronic device ED may include a folding portion FA and a plurality of non-folding portions NFA1 and NFA2. The non-folding portions NFA1 and NFA2 may include a first non-folding portion NFA1 and a second non-folding portion NFA2. The folding portion FA may be disposed between the first non-folding portion NFA1 and the second non-folding portion NFA2. The first non-folding portion NFA1, the folding portion FA, and the second non-folding portion NFA2 may be arranged in the first direction DR1.

In the present embodiment, one folding portion FA and two non-folding portions NFA1 and NFA2 are shown as a representative example, however, the number of the folding portions FA and the number of non-folding portions NFA1 and NFA2 is not limited thereto. As an example, the electronic device ED may include more than two non-folding portions and a plurality of folding portions disposed between the non-folding portions.

An upper surface of the electronic device ED may be referred to as a display surface DS, and the display surface DS may be a plane defined by the first direction DR1 and the second direction DR2. Images IM generated by the electronic device ED may be provided to a user through the display surface DS.

The display surface DS may include a display area DA and a non-display area NDA around the display area DA. The display area DA may display the image, and the non-display area NDA does not display the image. The non-display area NDA may surround or be adjacent to the display area DA and may define an edge of the electronic device ED, which is printed in a predetermined color.

The electronic device ED may include a plurality of sensors SN and at least one camera CM. The sensors SN and the camera CM may be disposed adjacent to the edge of the electronic device ED. The sensors SN and the camera CM may be disposed in the display area DA adjacent to the non-display area NDA. The sensors SN and the camera CM may be disposed in the first non-folding portion NFA1. However, locations of the sensors SN and the camera CM are not be limited thereto.

As an example, each sensor SN may be a proximity illumination sensor. However, the sensors SN are not limited thereto. The camera CM may take a picture of external objects.

Referring to FIG. 2, the electronic device ED may be a foldable electronic device ED that is folded or unfolded. As an example, the folding portion FA may be folded with respect to a folding axis FX substantially parallel to the second direction DR2, and thus, the electronic device ED may be folded. The folding axis FX of the electronic device ED may be defined as a minor axis substantially parallel to the short sides of the electronic device ED. The electronic device ED may be folded with respect to the folding axis FX substantially parallel to the short sides.

When the electronic device ED is folded, the electronic device ED may be inwardly folded (in-folding) such that the first non-folding portion NFA1 and the second non-folding portion NFA2 may face each other and the display surface DS is not exposed to the outside. However, the present disclosure is not limited thereto. As an example, the electronic device ED may be outwardly folded (out-folding) with respect to the folding axis FX such that the display surface DS may be exposed to the outside.

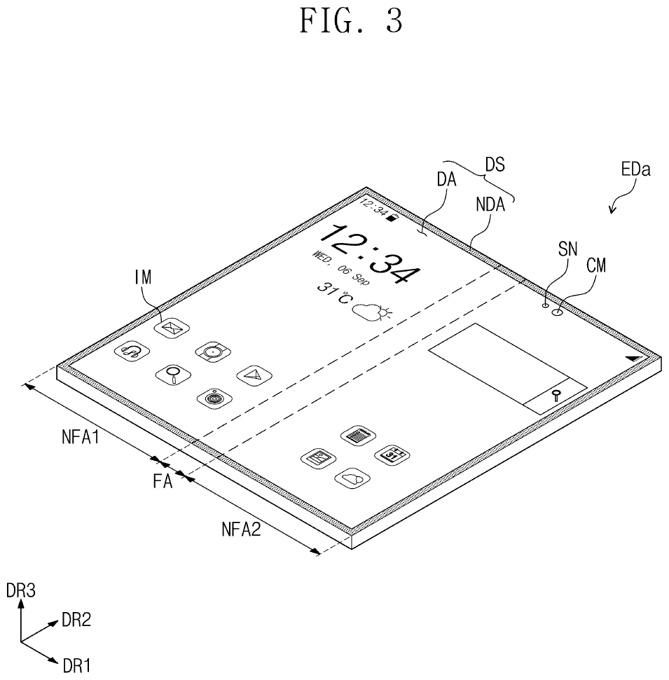

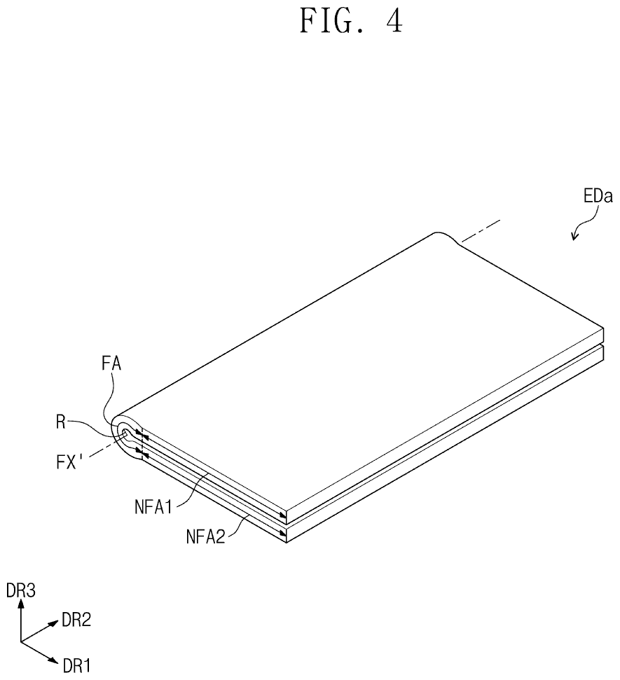

FIG. 3 is a perspective view of an electronic device EDa according to an embodiment of the present disclosure, and FIG. 4 is a perspective view of the electronic device EDa shown in FIG. 3 in folded state.

Referring to FIG. 3, the electronic device EDa may have a quadrangular shape defined by short sides extending in the first direction DR1 and long sides extending in the second direction DR2 intersecting the first direction DR1.

The electronic device EDa may include a first non-folding portion NFA1, a folding portion FA, and a second non-folding portion NFA2, which are arranged in the first direction DR1.

An upper surface of the electronic device EDa may be referred to as a display surface DS, and images IM generated by the electronic device EDa may be provided to the user through the display surface DS.

As with the electronic device ED (refer to FIG. 1), the electronic device EDa may include at least one sensor SN and at least one camera CM.

Referring to FIG. 4, the electronic device EDa may be a foldable electronic device EDa that is folded or unfolded. As an example, the folding portion FA may be folded with respect to a folding axis FX′ substantially parallel to the second direction DR2, and thus, the electronic device EDa may be folded. The folding axis FX of the electronic device ED shown in FIG. 2 may be the minor axis substantially parallel to the short sides of the electronic device ED. However, the folding axis FX′ of the electronic device EDa shown in FIG. 4 may be a major axis substantially parallel to the long sides of the electronic device EDa.

A distance between the first non-folding portion NFA1 and the second non-folding portion NFA2 may be smaller than a diameter of a circle defined by a radius of curvature R of the folding portion FA. Accordingly, the folding portion FA may be folded to have a dumbbell shape. Thus, the distance between the first non-folding portion NFA1 and the second non-folding portion NFA2 may be reduced. The electronic device ED may also be folded to have the dumbbell shape. Hereinafter, the electronic device ED shown in FIGS. 1 and 2 will be described as a representative example. In addition, components of the present disclosure will be described based on the electronic device ED that is folded into the dumbbell shape.

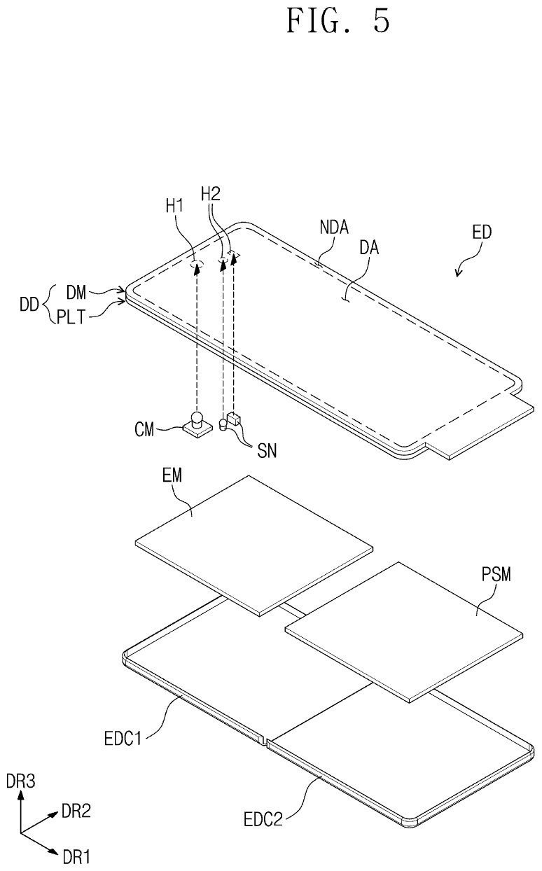

FIG. 5 is an exploded perspective view of the electronic device ED according to an embodiment of the present disclosure.

Referring to FIG. 5, the electronic device ED may include a display device DD including a display module DM and a support plate PLT, a camera CM, and sensors SN, and the electronic device ED may further include an electronic module EM (e.g., an electronic circuit), a power supply module PSM (e.g., a power supply circuit), and cases EDC1 and EDC2. The electronic device ED may further include a mechanical structure, e.g., a hinge structure, to control a folding operation of the electronic device ED.

The electronic device ED may include the display device DD provided with a first hole H1 defined therethrough to transmit optical signals. The first hole H1 and second holes H2 may be defined through the display device DD, the camera CM may be disposed in the first hole H1, and the sensors SN may be disposed in the second holes H2.

The electronic module EM and the power supply module PSM may be disposed under the display device DD. The electronic module EM and the power supply module PSM may be connected to each other by a flexible circuit board. The electronic module EM may control an operation of the display device DD. The power supply module PSM may supply power to the display device DD.

The cases EDC1 and EDC2 may accommodate the display device DD, the camera CM, the sensors SN, the electronic module EM, and the power supply module PSM. The cases EDC1 and EDC2 may be divided into two parts, such as the first and second cases EDC1 and EDC2, to enable the folding of the electronic device ED. Due to the structure of the first and second cases EDC1 and EDC2, the folding operation of the display device DD may be facilitated. The cases EDC1 and EDC2 may protect the display device DD, the camera CM, the sensors SN, the electronic module EM, and the power supply module PSM.

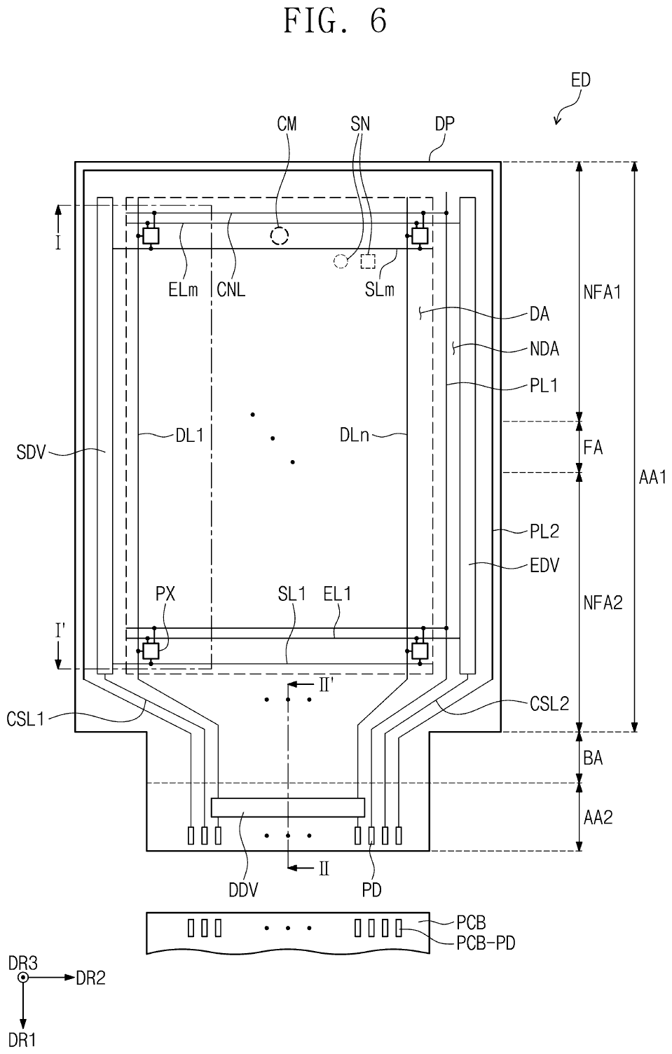

FIG. 6 is a plan view of a display panel DP applied to the electronic device ED shown in FIG. 1.

Referring to FIG. 6, the electronic device ED may include the display panel DP, a scan driver SDV (e.g., a first driver circuit), a data driver DDV (e.g., a second driver circuit), and an emission driver EDV (e.g., a third driver circuit).

The display panel DP may be a light emitting type display panel, but is not limited thereto. As an example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot or a quantum rod. Hereinafter, the organic light emitting display panel will be described as a representative example of the display panel DP.

The display panel DP may be a flexible display panel. As an example, the display panel DP may include a flexible substrate and a plurality of electronic elements disposed on the flexible substrate. The display panel DP may extend longer in the first direction DR1 than in the second direction DR2. The display panel DP may include a plane defined by the first direction DR1 and the second direction DR2.

The display panel DP may include a first area AA1, a second area AA2, and a bending area BA defined between the first area AA1 and the second area AA2. The bending area BA may extend in the second direction DR2, and the first area AA1, the bending area BA, and the second area AA2 may be arranged in the first direction DR1.

The first area AA1 may include long sides extending in the first direction DR1 and spaced apart from each other in the second direction DR2. The bending area BA and the second area AA2 may have a length smaller than a length of the first area AA1 in the second direction DR2.

The first area AA1 may include the display area DA and the non-display area NDA around the display area DA. The non-display area NDA may surround the display area DA. The display area DA may be an area in which the image is displayed, and the non-display area NDA may be an area in which the image is not displayed. The second area AA2 and the bending area BA may be areas in which the image is not displayed. The sensors SN and the camera CM may be disposed in the display area DA.

The first area AA1 may include the first non-folding area NFA1, the second non-folding area NFA2, and the folding area FA defined between the first non-folding area NFA1 and the second non-folding area NFA2. The first non-folding portion NFA1, the folding portion FA, and the second non-folding portion NFA2 of the display panel DP may correspond to the first non-folding portion NFA1, the folding portion FA, and the second non-folding portion NFA2 of the electronic device ED shown in FIG. 1, respectively.

The display panel DP may include a plurality of pixels PX, a plurality of scan lines SL1 to SLm (or gate lines), a plurality of data lines DL1 to DLn, a plurality of emission lines EL1 to ELm, first and second control lines CSL1 and CSL2, a first power line PL1, a second power line PL2, a plurality of connection lines CNL, and a plurality of pads PD. Each of m and n is a natural number. The pixels PX may be arranged in the display area DA and may be connected to the scan lines SL1 to SLm, the data lines DL1 to DLn, and the emission lines EL1 to ELm.

The scan driver SDV and the emission driver EDV may be disposed in the non-display area NDA. The scan driver SDV and the emission driver EDV may be disposed in the non-display area NDA to be respectively adjacent to both sides of the first area AA1. The data driver DDV may be disposed in the second area AA2. The data driver DDV may be manufactured in an integrated circuit chip form and may be mounted in the second area AA2.

The scan lines SL1 to SLm may extend in a direction parallel to the second direction DR2 and may be connected to the scan driver SDV. The data lines DL1 to DLn may extend in the first direction DR1 and may be connected to the data driver DDV via the bending area BA. The emission lines EL1 to ELm may extend in the second direction DR2 and may be connected to the emission driver EDV.

The first power line PL1 may extend in the first direction DR1 and may be disposed in the non-display area NDA. The first power line PL1 may be disposed between the display area DA and the emission driver EDV, but is not limited thereto. That is, the first power line PL1 may be disposed between the display area DA and the scan driver SDV.

The first power line PL1 may extend to the second area AA2 via the bending area BA. When viewed in a plane, the first power line PL1 may extend to a lower end of the second area AA2. The first power line PL1 may receive a first voltage.

The second power line PL2 may be disposed in the non-display area NDA adjacent to long sides of the first area AA1. The second power line PL2 may be disposed outside the scan driver SDV and the emission driver EDV.

The second power line PL2 may extend toward the second portion AA2 via the bending portion BA. Portions of the second power line PL2 may extend in the first direction DR1 with the data driver DDV interposed therebetween in the second area AA2. The second power line PL2 may extend to the lower end of the second portion AA2 when viewed in the plane.

The second power line PL2 may receive a second voltage having a level lower than that of the first voltage. The second power line PL2 may extend toward the display area DA and may be connected to the pixels PX, and the second voltage may be applied to the pixels PX via the second power line PL2.

The connection lines CNL may extend in the second direction DR2 and may be arranged in the first direction DR1. The connection lines CNL may be connected to the first power line PL1 and the pixels PX. The first voltage may be applied to the pixels PX via the first power line PL1 and the connection lines CNL connected to the first power line PL1.

The first control line CSL1 may be connected to the scan driver SDV and may extend toward the lower end of the second portion AA2 via the bending portion BA. The second control line CSL2 may be connected to the emission driver EDV and may extend toward the lower end of the second portion AA2 via the bending portion BA. The data driver DDV may be disposed between the first control line CSL1 and the second control line CSL2.

When viewed in the plane, the pads PD may be disposed adjacent to the lower end of the second portion AA2. The data driver DDV, the first power line PL1, the second power line PL2, the first control line CSL1, and the second control line CSL2 may be connected to the pads PD.

The data lines DL1 to DLn may be connected to corresponding pads PD via the data driver DDV. As an example, the data lines DL1 to DLn may be connected to the data driver DDV, and the data driver DDV may be connected to the pads PD corresponding to the data lines DL1 to DLn.

The electronic device ED may include a printed circuit board PCB connected to the pads PD. Connection pads PCB-PD may be disposed on the printed circuit board PCB, and the connection pads PCB-PD may be connected to the pads PD.

A timing controller may be disposed on the printed circuit board PCB. The timing controller may be connected to the pads PD via the printed circuit board PCB. The timing controller may control an operation of the scan driver SDV, the data driver DDV, and the emission driver EDV. The timing controller may generate a scan control signal, a data control signal, and an emission control signal in response to control signals applied thereto from the outside.

The scan control signal may be applied to the scan driver SDV via the first control line CSL1. The emission control signal may be applied to the emission driver EDV via the second control line CSL2. The data control signal may be applied to the data driver DDV. The timing controller may receive image signals from the outside, may convert a data format of the image signals to a data format appropriate to an interface between the timing controller and the data driver DDV, and may provide the converted image signals to the data driver DDV.

The scan driver SDV may generate a plurality of scan signals in response to the scan control signal. The scan signals may be applied to the pixels PX via the scan lines SL1 to SLm. The scan signals may be sequentially applied to the pixels PX.

The data driver DDV may generate a plurality of data voltages corresponding to the image signals in response to the data control signal. The data voltages may be applied to the pixels PX via the data lines DL1 to DLn. The emission driver EDV may generate a plurality of emission signals in response to the emission control signal. The emission signals may be applied to the pixels PX via the emission lines EL1 to ELm.

The pixels PX may receive the data voltages in response to the scan signals. The pixels PX may emit light having a luminance corresponding to the data voltages in response to the emission signals, and thus, the image may be displayed. An emission time of the pixels PX may be controlled by the emission signals.

A voltage generator may be disposed on the printed circuit board PCB. The voltage generator may be connected to the pads PD through the printed circuit board PCB. The voltage generator may generate the first voltage and the second voltage. The first voltage and the second voltage may be applied to the first power line PL1 and the second power line PL2, respectively.

Each of the pixels PX may include a light emitting element. The first voltage may be applied to an anode of the light emitting element, and the second voltage may be applied to a cathode of the light emitting element. The light emitting element may be driven in response to the first voltage and the second voltage.

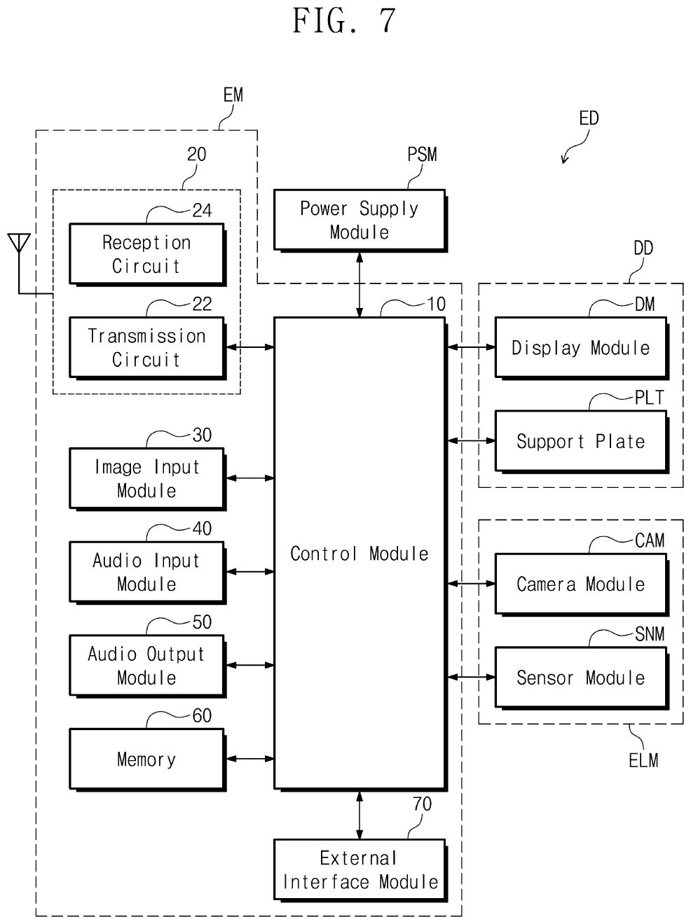

FIG. 7 is a block diagram of the electronic device ED shown in FIG. 5.

Referring to FIG. 7, the electronic device ED may include the electronic module EM, the power supply module PSM, the display device DD, and an electro-optical module ELM. The electronic module EM may include a control module 10 (e.g., a control circuit), a wireless communication module 20 (e.g., a wireless communication circuit), an image input module 30 (e.g., a first input circuit), an audio input module 40 (e.g., a second input circuit), an audio output module 50 (e.g., an output circuit), a memory 60, and an external interface module 70 (e.g., an interface circuit). The display device DD may include the display module DM and the support plate PLT. The modules 10, 20, 30, 40, 50, 60, and 70 may be mounted on a circuit board to be electrically connected to each other or may be electrically connected to each other through a flexible circuit board. The electronic module EM may be electrically connected to the power supply module PSM.

The control module 10 may control an overall operation of the electronic device ED. For example, the control module 10 may activate or deactivate the display device DD in response to a user's input. The control module 10 may control other modules, such as the image input module 30, the audio input module 40 or the audio output module 50, in response to the user's input. The control module 10 may include at least one microprocessor.

The wireless communication module 20 may transmit/receive a wireless signal to/from other terminals using Bluetooth or a WiFi link. The wireless communication module 20 may transmit/receive a voice signal using a general communication line. The wireless communication module 20 may include a transmission circuit 22 that modulates a signal to be transmitted and transmits the modulated signal and a reception circuit 24 that demodulates the signal applied thereto.

The image input module 30 may process an image signal and may convert the image signal into image data that may be displayed through the display device DD. The audio input module 40 may receive an external sound signal through a microphone in a record mode or a voice recognition mode and may convert the external sound signal to electrical voice data. The audio output module 50 may convert sound data provided thereto from the wireless communication module 20 or sound data stored in the memory 60 and may output the converted sound data.

The external interface module 70 may serve as an interface between the control module 10 and external devices, such as an external charger, a wired/wireless data port, a card socket (e.g., a memory card and a SIM/UIM card), etc.

The power supply module PSM may supply a power required for the overall operation of the electronic device ED. The power supply module PSM may include a conventional battery device.

The electro-optical module ELM may be an electronic component that transmits or receives the optical signal. The electro-optical module ELM may transmit or receive the optical signal through a partial area of the display device DD. In the present embodiment, the electro-optical module ELM may include a camera module CAM and a sensor module SNM. The camera module CAM may include the camera CA shown in FIG. 5. The sensor module SNM may include the sensor SN shown in FIG. 5.

The electro-optical module ELM may include the camera module CAM and the sensor module SNM, and the camera CM and the sensor SN may be disposed under the display device DD as shown in FIG. 5. Therefore, the electro-optical module ELM may be disposed under the display device DD and may overlap the first hole H1 and the second hole H2.

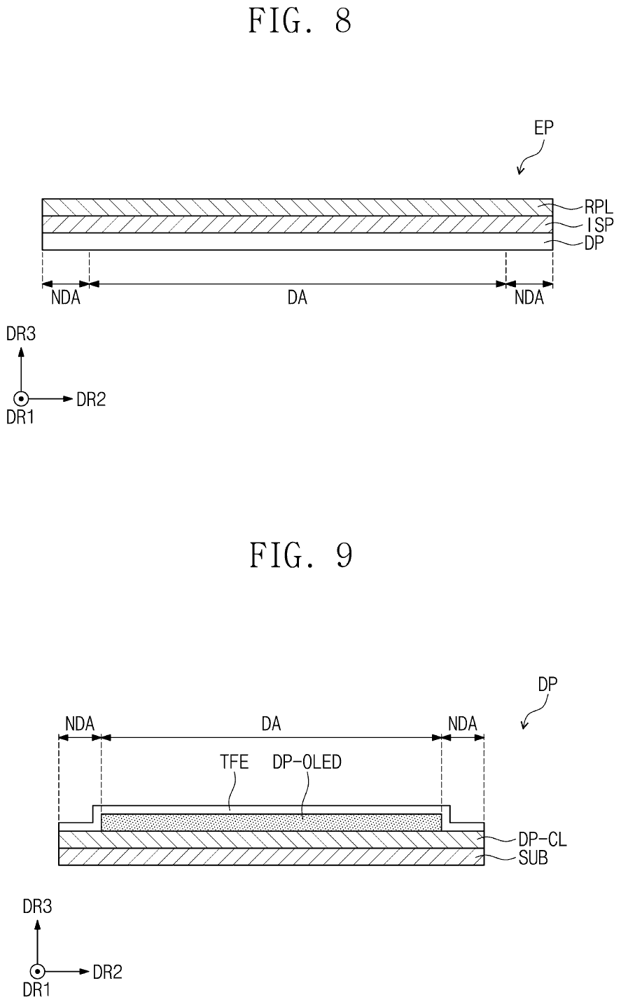

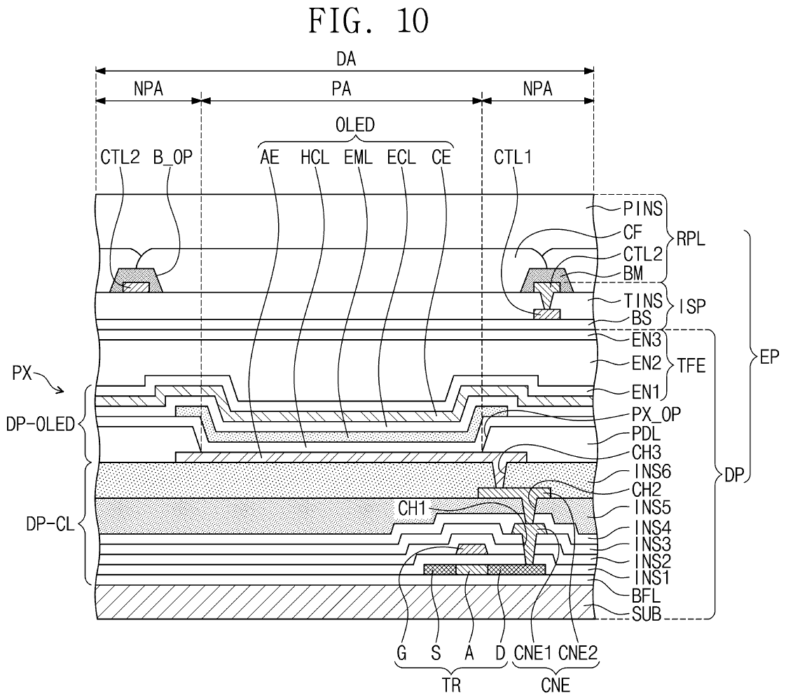

FIG. 8 is a cross-sectional view of an electronic panel EP including the display panel DP shown in FIG. 5, and FIG. 9 is a cross-sectional view of the display panel DP shown in FIG. 8.

FIGS. 8 and 9 respectively show the cross-sections of the electronic panel EP and the display panel DP when viewed in the first direction DR1.

Referring to FIG. 8, the electronic panel EP may include the display panel DP, an input sensing part ISP disposed on the display panel DP, and an anti-reflective layer RPL disposed on the input sensing part ISP.

The input sensing part ISP may include a plurality of sensing electrodes that operated using a capacitive method. The input sensing part ISP may include a plurality of pen sensing electrodes operating using an electromagnetic method. The input sensing part ISP may be manufactured directly on the display panel DP when the electronic panel EP is manufactured.

The anti-reflective layer RPL may be formed directly on the input sensing part ISP when the electronic panel EP is manufactured, but is not limited thereto. According to an embodiment, the anti-reflective layer RPL is attached to the input sensing part ISP by an adhesive layer after being manufactured separately.

The anti-reflective layer RPL may be defined as an external light reflection prevention film. The anti-reflective layer RPL may decrease a reflectance of an external light incident to the display panel DP from the above of the electronic device ED.

Referring to FIG. 9, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include the display area DA and the non-display area NDA around or adjacent to the display area DA. The display area DA may correspond to the display area DA of the electronic device ED shown in FIG. 1, and the non-display area NDA may correspond to the non-display area NDA of the electronic device ED shown in FIG. 1. The substrate SUB may include glass or a flexible plastic material, e.g., polyimide (PI). The display element layer DP-OLED may be disposed in the display area DA.

The pixels may be disposed in the circuit element layer DP-CL and the display element layer DP-OLED. Each of the pixels may include transistors disposed in the circuit element layer DP-CL and a light emitting element disposed in the display element layer DP-OLED and connected to the transistors.

The thin film encapsulation layer TFE may be disposed on the circuit element layer DP-CL to cover the display element layer DP-OLED. The thin film encapsulation layer TFE may protect the pixels from moisture, oxygen, and foreign substances.

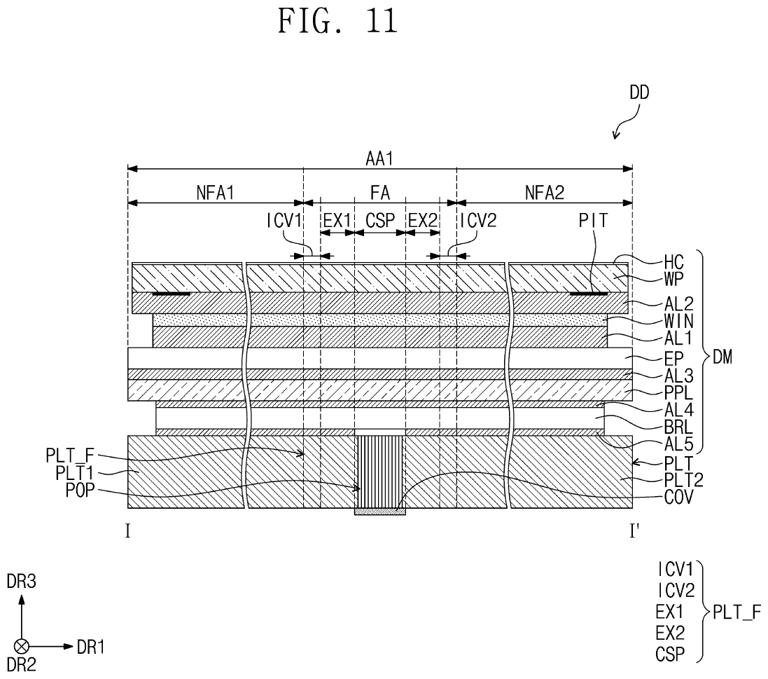

FIG. 10 is a cross-sectional view of the electronic panel corresponding to one pixel shown in FIG. 6.

Referring to FIG. 10, the display panel DP may include the pixel PX, and the pixel PX may include a transistor TR and a light emitting element OLED. The light emitting element OLED may include a first electrode (or an anode) AE, a second electrode (or a cathode) CE, a hole control layer HCL, an electron control layer ECL, and a light emitting layer EML.

The transistor TR and the light emitting element OLED may be disposed on the substrate SUB. As an example, one transistor TR is shown in FIG. 10, however, the pixel PX may include a plurality of transistors and at least one capacitor to drive the light emitting element OLED.

The display area DA may include a light emitting area PA corresponding to each pixel PX and a non-light-emitting area NPA around the light emitting area PA. The light emitting element OLED may be disposed in the light emitting area PA.

A buffer layer BFL may be disposed on the substrate SUB, and the buffer layer BFL may be an inorganic layer. A semiconductor pattern may be disposed on the buffer layer BFL. The semiconductor pattern may include polycrystalline silicon, amorphous silicon, or metal oxide.

The semiconductor pattern may be doped with an N-type dopant or a P-type dopant. The semiconductor pattern may include a high-doped region and a low-doped region. The high-doped region may have a conductivity greater than that of the low-doped region and may substantially serve as a source electrode and a drain electrode of the transistor TR. The low-doped region may substantially correspond to an active (or a channel) of the transistor TR.

A source S, an active A (or active region), and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 to connect the transistor TR to the light emitting element OLED. The first connection electrode CNE1 may be disposed on the third insulating layer INS3 and may be connected to the drain D via a first contact hole CH1 defined through the first, second, and third insulating layers INS1, INS2, and INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 via a second contact hole CH2 defined through the fourth insulating layer INS4 and the fifth insulating layer INS5.

A sixth insulating layer INS6 may be disposed on the second connection electrode CNE2. Each layer from the buffer layer BFL to the sixth insulating layer INS6 may be defined as a circuit element layer DP-CL. Each of the first to sixth insulating layers INS1 to INS6 may be an inorganic layer or an organic layer.

The first electrode AE may be disposed on the sixth insulating layer INS6. The first electrode AE may be connected to the second connection electrode CNE2 via a third contact hole CH3 defined through the sixth insulating layer INS6. A pixel definition layer PDL may be disposed on the first electrode AE and the sixth insulating layer INS6. The pixel definition layer PDL may be provided with a pixel opening PX_OP defined therethrough to expose a predetermined portion of the first electrode AE.

The hole control layer HCL may be disposed on the first electrode AE and the pixel definition layer PDL. The hole control layer HCL may include a hole transport layer and a hole injection layer.

The light emitting layer EML may be disposed on the hole control layer HCL. The light emitting layer EML may be disposed in an area corresponding to the pixel opening PX_OP. The light emitting layer EML may include an organic material and/or an inorganic material. The light emitting layer EML may generate a light having one of red, green, and blue colors.

The electron control layer ECL may be disposed on the light emitting layer EML and the hole control layer HCL. The electron control layer ECL may include an electron transport layer and an electron injection layer. The hole control layer HCL and the electron control layer ECL may be commonly disposed in the light emitting area PA and the non-light-emitting area NPA.

The second electrode CE may be disposed on the electron control layer ECL. The second electrode CE may be commonly disposed over the pixels PX. A layer on which the light emitting element OLED is disposed may be referred to as the display element layer DP-OLED.

The thin film encapsulation layer TFE may be disposed on the second electrode CE to cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulating layer and may protect the pixel PX from moisture and oxygen. The second encapsulation layer EN2 may include an organic insulating layer and may protect the pixel PX from a foreign substance such as dust particles.

The first voltage may be applied to the first electrode AE via the transistor TR, and the second voltage having a voltage level lower than that of the first voltage may be applied to the second electrode CE. Holes and electrons injected into the light emitting layer EML may be recombined to generate excitons, and the light emitting element OLED may emit the light by the excitons that return to a ground state from an excited state.

Layers from the substrate SUB to the thin film encapsulation layer TFE may be defined as the display panel DP. The input sensing part ISP may be disposed on the thin film encapsulation layer TFE. The input sensing part ISP may be directly manufactured on an upper surface of the thin film encapsulation layer TFE.

A base layer BS may be disposed on the thin film encapsulation layer TFE. The base layer BS may include an inorganic insulating layer. At least one inorganic insulating layer may be provided on the thin film encapsulation layer TFE as the base layer BS.

The input sensing part ISP may include a first conductive pattern CTL1 and a second conductive pattern CTL2 disposed on the first conductive pattern CTL1. The first conductive pattern CTL1 may be disposed on the base layer BS. An insulating layer TINS may be disposed on the base layer BS to cover the first conductive pattern CTL1. The insulating layer TINS may include an inorganic insulating layer or an organic insulating layer. The second conductive pattern CTL2 may be disposed on the insulating layer TINS.

The first and second conductive patterns CTL1 and CTL2 may overlap the non-light-emitting area NPA. Although not shown in figures, the first and second conductive patterns CTL1 and CTL2 may be disposed in the non-light-emitting area NPA between the light emitting areas PA and may have a mesh shape.

The first and second conductive patterns CTL1 and CTL2 may form the sensing electrodes and the pen sensing electrodes of the input sensing part ISP. As an example, the first and second conductive patterns CTL1 and CTL2 having a mesh shape may be separated from each other in a predetermined area to form the sensors and the pen sensing electrodes. A portion of the second conductive pattern CTL2 may be connected to the first conductive pattern CTL1.

The anti-reflective layer RPL may be disposed on the second conductive pattern CTL2. The anti-reflective layer RPL may include a black matrix BM and a plurality of color filters CF. The black matrix BM may overlap the non-light-emitting area NPA, and the color filters CF may overlap the light emitting areas PA, respectively.

The black matrix BM may be disposed on the insulating layer TINS to cover the second conductive pattern CTL2. The black matrix BM may be provided with a black opening B_OP defined therethrough to overlap the light emitting area PA and the pixel opening PX_OP. The black matrix BM may absorb and block the light. A width of the black opening B_OP may be greater than a width of the pixel opening PX_OP.

The color filters CF may be disposed on the insulating layer TINS and the black matrix BM. The color filters CF may be disposed in the black openings B_OP, respectively. A planarization insulating layer PINS may be disposed on the color filters CF. The planarization insulating layer PINS may provide a flat upper surface.

In a case where the external light incident to the display panel DP is provided to the user after being reflected by the display panel DP, like a mirror, the user may perceive the external light. The anti-reflective layer RPL may include the color filters CF that display the same colors as those of the pixels to prevent the above-mentioned phenomenon. The color filters may filter the external light to have the same color as the pixels. In this case, the external light may not be perceived by the user.

However, the present disclosure is not limited thereto, and the anti-reflective layer RPL may include a polarizing film to reduce the reflectance of the external light. The polarizing film may be attached to the input sensing part ISP by an adhesive layer after being manufactured separately. The polarizing film may include a retarder and/or a polarizer.

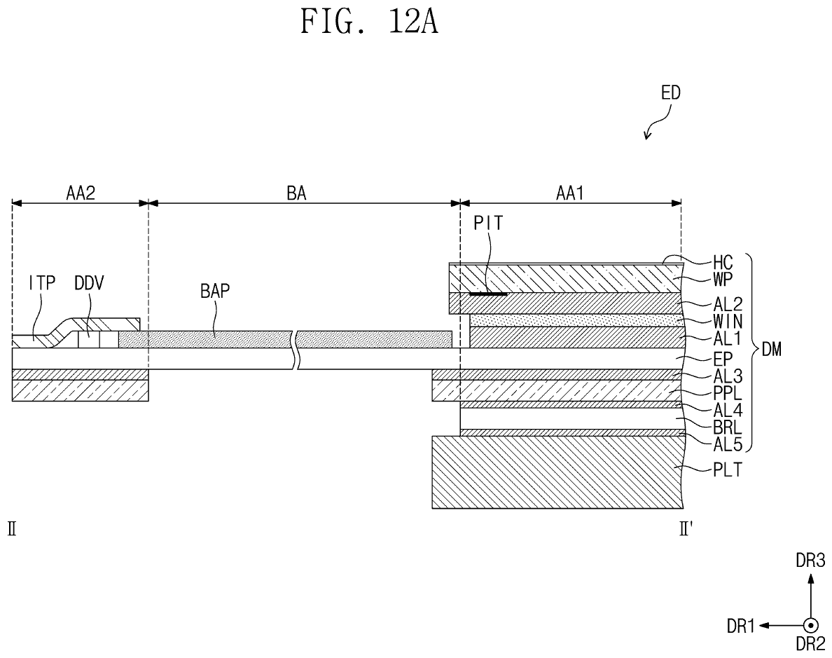

FIG. 11 is a cross-sectional view taken along a line I-I′ shown in FIG. 6.

As an example, FIG. 11 shows a cross-section of the display module DM and a cross-section of components disposed under the display module DM, which are taken along the line I-I′ of FIG. 6.

Referring to FIG. 11, the display device DD may include the display module DM, the support plate PLT, and a cover layer COV. The display module DM may include a hard coating layer HC, a print layer PIT, a window WIN, a window protective layer WP, an impact absorbing layer ISL, the electronic panel EP, and a panel protective layer PPL. The display device DD may include first, second, third, fourth, and fifth adhesive layers AL1, AL2, AL3, AL4, and AL5 to attach the above components to each other.

In an embodiment, the display module DM includes the first non-folding portion NFA1, the folding portion FA, and the second non-folding portion NFA2. As the folding portion FA is folded with respect to the folding axis FX (refer to FIG. 2), the display module DM may be folded.

The window WIN may be disposed on the electronic panel EP. The window WIN may protect the electronic panel EP from objects that cause scratches. The window WIN may have an optically transparent property. The window WIN may include a glass material, but is not limited thereto. According to an embodiment, the window WIN includes a synthetic resin film.

The window WIN may have a single-layer or multi-layer structure. As an example, the window WIN may include a plurality of synthetic resin films attached to each other by an adhesive or a glass substrate and the synthetic resin film attached to the glass substrate by an adhesive.

The window protective layer WP may be disposed on the window WIN. The window protective layer WP may include a flexible plastic material, such as polyimide (PI) or polyethylene terephthalate (PET). The hard coating layer HC may be disposed on the window protective layer WP.

The print layer PIT may be disposed on a lower surface of the window protective layer WP. The print layer PIT may have a black color but is not limited thereto. The print layer PIT may be disposed adjacent to an edge of the window protective layer WP.

The panel protective layer PPL may be disposed under the electronic panel EP. The panel protective layer PPL may protect a lower portion of the electronic panel EP. The panel protective layer PPL may include a flexible plastic material. As an example, the panel protective layer PPL may include polyethylene terephthalate (PET).

A barrier layer BRL may be disposed under the panel protective layer PPL. The barrier layer BRL may increase a resistance to a compressive force caused by an external pressure. Accordingly, the barrier layer BRL may prevent the electronic panel EP from being deformed. The barrier layer BRL may include a flexible plastic material, such as polyimide or polyethylene terephthalate.

The barrier layer BRL may have a color that absorbs light. As an example, the barrier layer BRL may have a black color. Accordingly, when looking at the display module DM from an upper side of the display module DM, components disposed under the barrier layer BRL may not be visible to a user.

The first adhesive layer AL1 may be disposed between the window WIN and the electronic panel EP. The window WIN may be attached to the electronic panel EP by the first adhesive layer AL1. An extension length in the first direction DR1 of the first adhesive layer AL1 may be substantially the same an extension length in the first direction DR1 of the window WIN. In an embodiment, a side surface of the first adhesive layer AL1 is aligned with a side surface of the window WIN. For example, the edges of both the first adhesive layer AL1 and the window WIN may coincide or be positioned in the same plane when viewed from the side. FIG. 11 shows a structure in which the first adhesive layer AL1 is aligned with the window WIN when viewed in the cross-section. However in another embodiment, the first adhesive layer AL1 may be recessed further inward a direction parallel to the first direction DR1, as long as it remains positioned between the window WIN and the electronic panel EP to secure the attachment of the window WIN. For example, in this configuration, the side surface of the window WIN may extend beyond the side surface of the first adhesive layer AL1 in the direction parallel to the first direction DR1.

The second adhesive layer AL2 may be disposed between the window WIN and the window protective layer WP. The window WIN may be attached to the window protective layer WP by the second adhesive layer AL2. The second adhesive layer AL2 may cover the print layer PIT.

The third adhesive layer AL3 may be disposed between the electronic panel EP and the panel protective layer PPL. The panel protective layer PPL may be attached to the electronic panel EP by the third adhesive layer AL3.

The fourth adhesive layer AL4 may be disposed under the panel protective layer PPL. The fourth adhesive layer AL4 may be disposed between the panel protective layer PPL and the barrier layer BRL. The barrier layer BRL may be attached to the panel protective layer PPL by the fourth adhesive layer AL4.

The fifth adhesive layer AL5 may be disposed under the barrier layer BRL. The fifth adhesive layer AL5 may be disposed between the barrier layer BRL and the support plate PLT. The support plate PLT may be attached to the barrier layer BRL by the fifth adhesive layer AL5. In an embodiment, the fifth adhesive layer AL5 is disposed in an area that does not overlap a curved portion CSP. For example, the fifth adhesive layer AL5 may be disposed in an area adjacent to the curved portion CSP while remaining separate from the curved portion CSP. A portion of the fifth adhesive layer AL5, which overlaps the curved portion CSP, may be opened. For example, the fifth adhesive layer AL5 may include separate sections positioned on either side of the curved portion CSP, leaving an open region in the area corresponding to CSP.

The first to fifth adhesive layers AL1 to AL6 may include a transparent adhesive such as a pressure sensitive adhesive (PSA) or an optically clear adhesive (OCA), but is not limited thereto.

The support plate PLT may be disposed under the display module DM and may support the display module DM. The support plate PLT may include a non-metallic material. As an example, the support plate PLT may include a fiber reinforced composite. The fiber reinforced composite may include a carbon fiber reinforced plastic (CFRP) or a glass fiber reinforced plastic (GFRP).

Since the support plate PLT includes the fiber reinforced composite, the support plate PLT may be lightweight. As the support plate PLT includes the fiber reinforced composite, the support plate PLT may have a light weight compared with a metal support plate formed of a metal material and may have a level of modulus and strength similar to those of the metal support plate.

In addition, since the support plate PLT includes the fiber reinforced composite, a shape machining process of the support plate PLT may be simpler compared with the metal support plate. As an example, the support plate PLT including the fiber reinforced composite may be processed by using a laser process or a micro-blast process.

In an embodiment, a plurality of openings POP is present in a portion of the support plate PLT, which overlaps the folding area FA. The openings POP may be formed through the portion of the support plate PLT in the third direction DR3. The openings POP may be formed by the laser process or the micro-blast process. The opening POP may be uniformly spaced apart from one another.

The support plate PLT may include a first support plate PLT1, a second support plate PLT2, and a support folding portion PLT_F. As an example, boundaries of the first support plate PLT1, the second support plate PLT2, and the support folding portion PLT_F are depicted as dotted lines as shown in FIG. 11.

The support folding portion PLT_F may be disposed between the first support plate PLT1 and the second support plate PLT2. The first support plate PLT1, the support folding portion PLT_F, and the second support plate PLT2 may be arranged in the first direction DR1. The openings POP may be present in the support folding portion PLT_F. The openings POP may be through-holes of the support folding portion PLT_F.

In the present disclosure, the term “overlap” may refer to a state in which components of the display device are arranged to overlap each other when viewed in the plane.

The first support plate PLT1 may be disposed in the first non-folding portion NFA1 and may overlap the first non-folding portion NFA1. The second support plate PLT2 may be disposed in the second non-folding portion NFA2 and may overlap the second non-folding portion NFA2. The support folding portion PLT_F may be disposed in the folding portion FA and may overlap the folding portion FA.

In an embodiment, the support folding portion PLT_F includes the curved portion CSP, a first extension portion EX1, a second extension portion EX2, a first reverse curvature portion ICV1, and a second reverse curvature portion ICV2. Boundaries between the curved portion CSP, the first extension portion EX1, the second extension portion EX2, the first reverse curvature portion ICV1, and the second reverse curvature portion ICV2 are depicted by dotted lines as shown in FIG. 11. For convenience of explanation, the dotted lines extend upward to depict the reference numerals of these components at an upper side of the display module DM in FIG. 11.

The curved portion CSP, the first extension portion EX1, the second extension portion EX2, the first reverse curvature portion ICV1, and the second reverse curvature portion ICV2 may be arranged in the first direction DR1. As an example, the curved portion CSP may be disposed at a center of the support folding portion PLT_F. The first reverse curvature portion ICV1 may be defined as a portion of the support folding portion PLT_F, which is adjacent to the first support plate PLT1. The second reverse curvature portion ICV2 may be defined as a portion of the support folding portion PLT_F, which is adjacent to the second support plate PLT2.

The curved portion CSP may be disposed between the first extension portion EX1 and the second extension portion EX2. The openings POP may be defined through the curved portion CSP. For example, through-holes may present in the curved portion CSP. When the support folding portion PLT_F is folded, the curved portion CSP may be curved to have a predetermined curvature. As the openings POP are defined through the curved portion CSP, the flexibility of the curved portion CSP may increase. As a result, the curved portion CSP may be folded more easily.

The first extension portion EX1 may be disposed between the first reverse curvature portion ICV1 and the curved portion CSP. The second extension portion EX2 may be disposed between the second reverse curvature portion ICV2 and the curved portion CSP.

The first reverse curvature portion ICV1 may be disposed between the first support plate PLT1 and the curved portion CSP. In detail, the first reverse curvature portion ICV1 may be disposed between the first support plate PLT1 and the first extension portion EX1. The second reverse curvature portion ICV2 may be disposed between the second support plate PLT2 and the curved portion CSP. In detail, the second reverse curvature portion ICV2 may be disposed between the second support plate PLT2 and the second extension portion EX2.

The cover layer COV may be disposed under the support plate PLT. In an embodiment, the cover layer COV covers the openings POP defined through the support plate PLT under the support plate PLT. The cover layer COV may overlap the curved portion CSP of the support folding portion PLT_F. The cover layer COV may be in contact with a lower surface of the curved portion CSP through which the openings POP are formed.

In an embodiment, the cover layer COV has a modulus of elasticity lower than that of the support plate PLT. As an example, the cover layer COV may include thermoplastic polyurethane or rubber, but is not limited thereto. The cover layer COV may be manufactured in the form of a sheet and may be attached to the support plate PLT.

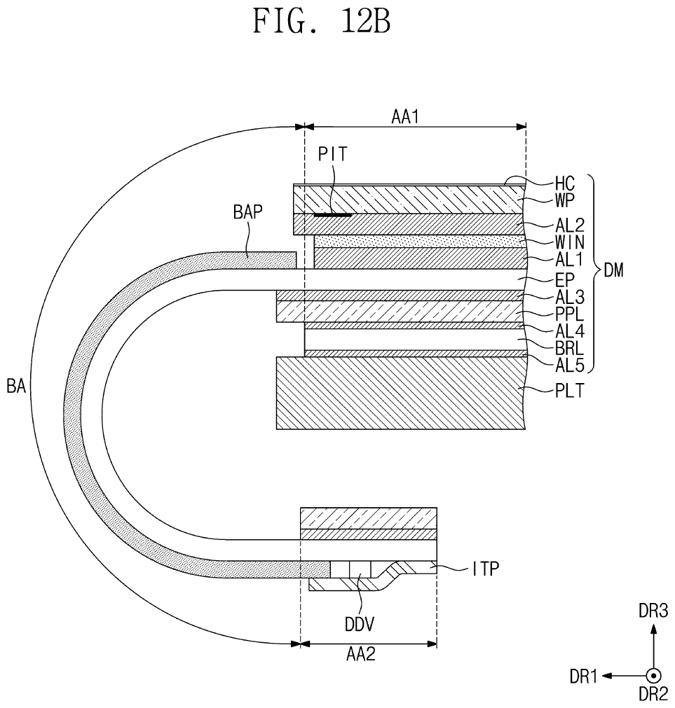

FIG. 12A is a cross-sectional view taken along a line II-II′ shown in FIG. 6, and FIG. 12B is a cross-sectional view of a folded state of the bending area BA shown in FIG. 12A.

While the panel protective layer PPL and the third adhesive layer AL3 are shown in FIG. 12A extending into the bending area BA, in an alternate embodiment, they may be shortened so as not to extend into the bending area BA. The panel protective layer PPL and the third adhesive layer AL3 may be disposed under the electronic panel EP in the second area AA2. The data driver DDV (refer to FIG. 6) may be disposed in the second area AA2 of the electronic panel EP.

The electronic device ED may further include a bending protective layer BAP. The bending protective layer BAP may be disposed in the bending area BA, a portion of the first area AA1 adjacent to the bending area BA, and a portion of the second area AA2 adjacent to the bending area BA. The bending protective layer BAP may extend from the portion of the first area AA1 adjacent to the bending area BA to the portion of the second area AA2 adjacent to the bending area BA without being disconnected. In an embodiment, the bending protective layer BAP is spaced apart from the first adhesive layer AL1. For example, a gap may be present in part of the bending area BA and part of the first area AA1 that is adjacent an edge of the bending protective layer BAP and an edge of the first adhesive layer AL1.

Referring to FIG. 12B, the bending protective layer BAP and electronic panel ED disposed in the bending area BA may be bent to have a predetermined curvature. When the bending protective layer BAP and electronic panel ED disposed in the bending area BA is bent, electronic panel ED disposed in the second area AA2 may be disposed under the electronic panel ED disposed in the first area AA1. Accordingly, the data driver DDV (refer to FIG. 6) may be disposed under the second area AA2.

In an embodiment, the electronic device ED disposed in the second area AA2 further includes an insulating tape ITP disposed under the second area AA2 to cover the data driver DDV. The insulating tape ITP may be disposed under a portion of the bending protective layer BAP in the second area AA2. For example, the insulating tape ITP may extend from part of the electronic panel EP to part of the bending protective layer BAP to cover the data driver DDV.

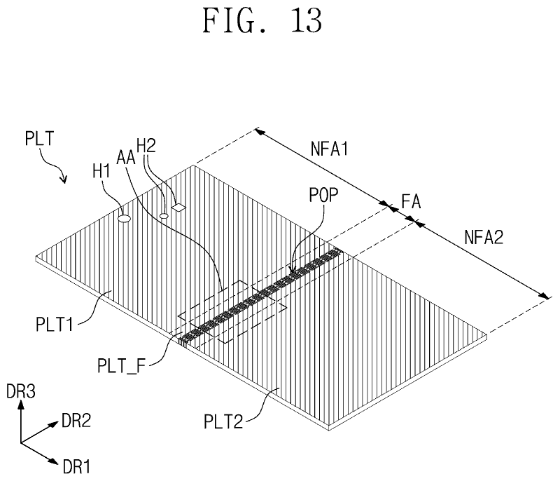

FIG. 13 is a perspective view of the support plate shown in FIG. 11.

Referring to FIG. 13, the support plate PLT may include the first non-folding portion NFA1, the folding portion FA, and the second non-folding portion NFA2, which are arranged in first direction DR1. The openings POP defined through the folding portion FA may be arranged in a grid shape. For example, the openings POP in the folding portion FA may be organized in a structured, grid-like pattern rather than being randomly placed.

Referring to FIGS. 5 and 13, the first hole H1 and the second holes H2 may be defined through the first support plate PLT1 in the first non-folding portion NFA1. The first hole H1 and the second holes H2 may be adjacent to an edge of the first support plate PLT1 in the first non-folding portion NFA1. The first hole H1 may correspond to the first hole H1 shown in FIG. 5, and the camera CM may be disposed in the first hole H1. The second holes H2 may correspond to the second holes H2 shown in FIG. 5, and the sensors SN may be disposed in the second holes H2.

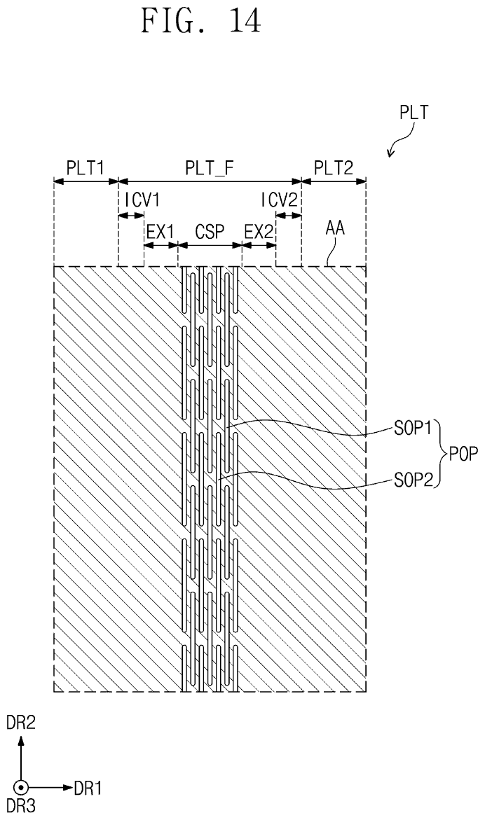

FIG. 14 is an enlarged plan view of an area AA shown in FIG. 13.

Referring to FIGS. 13 and 14, the support plate PLT may include the first support plate PLT1, the support folding portion PLT_F, and the second support plate PLT2, which are arranged in the first direction DR1. The support folding portion PLT_F may include the first reverse curvature portion ICV1, the first extension portion EX1, the curved portion CSP, the second extension portion EX2, and the second reverse curvature portion ICV2, which are arranged in the first direction DR1.

A grid pattern may be defined in the curved portion CSP. As an example, the openings POP defined through the curved portion CSP may be arranged according to a predetermined rule. The openings POP may be arranged in the grid shape to form the grid pattern of the curved portion CSP.

In an embodiment, the openings POP extend longer in the second direction DR2 than in the first direction DR1. The openings POP may include a plurality of first sub-openings SOP1 arranged in the second direction DR2 and a plurality of second sub-openings SOP2 adjacent to the first sub-openings SOP1 in the first direction DR1 and arranged in the second direction DR2. The first sub-openings SOP1 may be arranged in a staggered manner relative to the second sub-openings SOP2. For example, a part of the support plate PLT may be present between a pair of the first sub-openings SOP1 in the second direction such that one of the second sub-openings SOP2 overlaps this part and portions of the pair and is spaced apart from the pair in the first direction DR1.

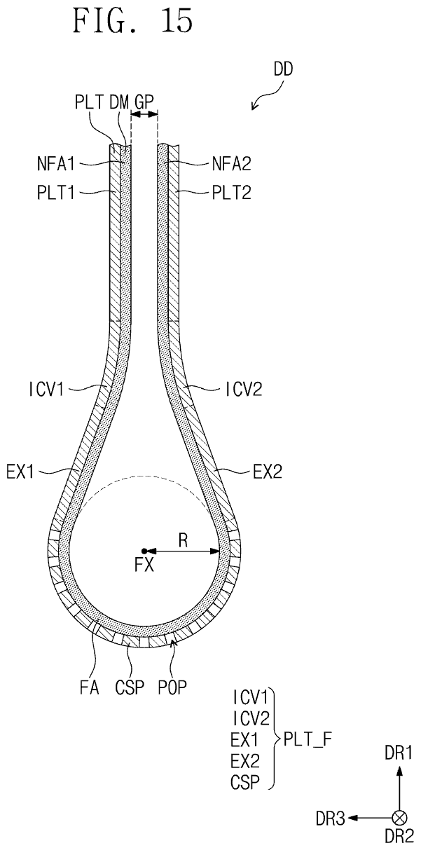

FIG. 15 is a view of the display device DD shown in FIG. 11 in a folded state.

As an example, the display module DM is illustrated as a single layer in FIG. 15. In addition, for the convenience of explanation, the display module DM and the support plate PLT are shown together, and other components are omitted.

As an example, the boundaries between the first and second support plates PLT1 and PLT2, the curved portion CSP, the first and second extension portions EX1 and EX2, and the first and second reverse curvature portions ICV1 and ICV2 are depicted by dotted lines as shown in FIG. 15.

Referring to FIGS. 11 and 15, the support plate PLT may be folded with respect to the folding axis FX. The support plate PLT may be folded into a dumbbell shape. As the support plate PLT is folded, the display module DM may be folded together with the support plate PLT.

The support folding portion PLT_F may be folded with respect to the folding axis FX, and thus, the support plate PLT may be folded. When the support folding portion PLT_F is folded, the curved portion CSP may be curved to have a predetermined curvature. As an example, the folding portion FA of the display module DM on the curved portion CSP may be curved to have a radius of curvature R.

The first reverse curvature portion ICV1 may be curved opposite to a curve of the curved portion CSP. The second reverse curvature portion ICV2 may be curved opposite to the curved portion CSP. The second reverse curvature portion ICV2 may have a shape symmetrical to the first reverse curvature portion ICV1.

When the support folding portion PLT_F is folded, the first support plate PLT1 and the second support plate PLT2 may be maintained in a flat state. Accordingly, the first and second non-folding portions NFA1 and NFA2 may be maintained in a flat state by the first and second support plates PLT1 and PLT2.

When the support folding portion PLT_F is folded, a distance GP in the first direction DR1 between the first support plate PLT1 and the second support plate PLT2 may be smaller than a diameter of a circle with a radius of curvature R. Accordingly, the support plate PLT may be folded into the dumbbell shape.

The first extension portion EX1 may be maintained in the flat state between the curved portion CSP and the first reverse curvature portion ICV1. The first extension portion EX1 may extend from the first reverse curvature portion ICV1 to the curved portion CSP and may be flat.

The second extension portion EX2 may be maintained in the flat state between the curved portion CSP and the second reverse curvature portion ICV2. The second extension portion EX2 may extend from the second reverse curvature portion ICV2 to the curved portion CSP and may be flat.

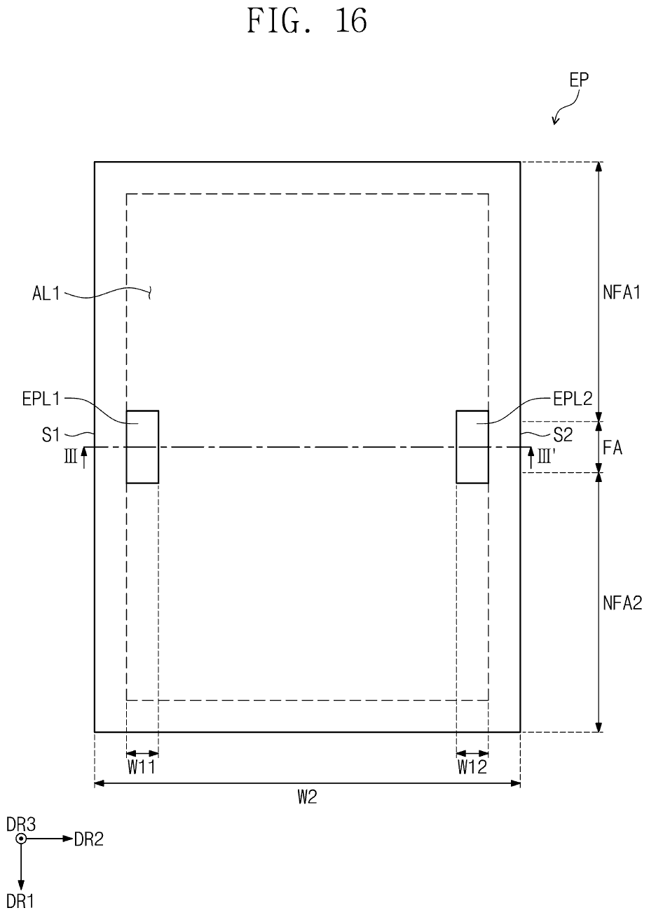

FIG. 16 is a plan view of the electronic panel EP and protective layers disposed on the electronic panel EP shown in FIG. 11.

Referring to FIG. 16, the electronic panel EP may include the folding portion FA and the non-folding portions NFA1 and NFA2, which are arranged in a direction parallel to the first direction DR1. In an embodiment, the folding portion FA includes a first side S1 and a second side S2 opposite to the first side S1 in the second direction DR2 intersecting the first direction DR1. The first side S1 may extend in the first direction DR1 and may be one of both sides S1 and S2 of the folding portion FA of the electronic panel EP. The second side S2 may extend in the first direction DR1 and may be the other of the both sides S1 and S2 of the folding portion FA of the electronic panel EP.

The display device DD (refer to FIG. 5) may include a plurality of protective layers EPL1 and EPL2 disposed on the electronic panel EP, and the protective layers EPL1 and EPL2 may extend in the first direction DR1 to overlap edges of the first adhesive layer AL1, which are opposite to each other in the second direction DR2. The protective layers EPL1 and EPL2 may include a first protective layer EPL1 and a second protective layer EPL2.

The first protective layer EPL1 may be disposed on the electronic panel EP. The first protective layer EPL1 may extend in the first direction DR1. The first protective layer EPL1 may be disposed in the folding portion FA of the electronic panel EP. The first protective layer EPL1 may be adjacent to the first side S1. The first protective layer EPL1 may enhance the rigidity of the side surface of the electronic panel EP extending in the first direction DR1. The first protective layer EPL1 may overlap the folding portion FA to protect the side surface of the electronic panel EP and may be further disposed in the first non-folding portion NFA1 and the second non-folding portion NFA2, which are adjacent to the folding portion FA. That is, the first protective layer EPL1 may extend into part of the first non-folding portion NFA1 and into part of the second non-folding portion NFA2, which are adjacent to the folding portion FA.

When viewed in the plane, an edge of the first protective layer EPL1, which faces outward, may be spaced apart from the first side S1. The first protective layer EPL1 may be spaced apart from the first side S1 by a predetermined distance in the second direction DR2. As an example, when viewed in the plane, the edge of the first protective layer EPL1, which faces outward, may overlap one side surface of the first adhesive layer AL1.

When viewed in the plane, the first protective layer EPL1 may have a rectangular shape with long sides extending in the first direction DR1 and short sides extending in the second direction DR2.

Hereinafter, a term “width” may refer to a length measured in the second direction DR2.

The first protective layer EPL1 may have a first-first width W11 in the second direction DR2. The folding portion FA may have a second width W2 in the second direction DR2. The first-first width W11 may be smaller than the second width W2.

When the first-first width W11 is smaller than the second width W2, the first protective layer EPL1 should not exert influence on the folding operation of the electronic panel EP when the electronic panel EP is folded in the folding portion FA. As an example, the first-first width W11 may be within a range from about 10% to about 15% of the second width W2.

The second protective layer EPL2 may be disposed on the electronic panel EP. The second protective layer EPL2 may be spaced apart from the first protective layer EPL1 in the second direction DR2 and may extend in the first direction DR1. The second protective layer EPL2 may be disposed in the folding portion FA of the electronic panel EP. The second protective layer EPL2 may be disposed adjacent to the second side S2. The second protective layer EPL2 may enhance the rigidity of the side surface of the electronic panel EP extending in the first direction DR1. The second protective layer EPL2 may overlap the folding portion FA to protect the side surface of the electronic panel EP and may be further disposed in the first non-folding portion NFA1 and the second non-folding portion NFA2, which are adjacent to the folding portion FA. That is, the second protective layer EPL2 may extend into part of the first non-folding portion NFA1 and into part of the second non-folding portion NFA2, which are adjacent to the folding portion FA.

When viewed in the plane, an edge of the second protective layer EPL2, which faces outward, may be spaced apart from the second side S2. The second protective layer EPL2 may be spaced apart from the second side S2 by a predetermined distance in the second direction DR2. As an example, when viewed in the plane, the edge of the second protective layer EPL2, which faces outward, may overlap one side surface of the first adhesive layer AL1.

When viewed in the plane, the second protective layer EPL2 may have a rectangular shape with long sides extending in the first direction DR1 and short sides extending in the second direction DR2.

The side surface of the first adhesive layer AL1, which overlaps the first protective layer EPL1, and the side surface of the first adhesive layer AL1, which overlaps the second protective layer EPL2, may be opposite to each other in the second direction DR2. An end of the second protective layer EPL2 may overlap an end of the first adhesive layer AL1, which is recessed from the second side S2 to a direction opposite to the second direction DR2. A portion of the edge of the second protective layer EPL2 may be parallel to the side surface of the first adhesive layer AL1 in the folding portion FA.

The second protective layer EPL2 may have a first-second width W12 in the second direction DR2. The first-second width W12 may be smaller than the second width W2. When the first-second width W12 is smaller than the second width W2, the second protective layer EPL2 should not exert influence on the folding operation of the electronic panel EP when the electronic panel EP is folded in the folding portion FA. As an example, the first-second width W12 may be within a range from about 10% to about 15% of the second width W2.

When the electronic panel EP is repeatedly folded and unfolded, cracks may occur due to the concentration of stress applied to the both sides S1 and S2 of the folding portion FA, which are opposite to each other in the second direction DR2. Due to the stress, the cracks may occur in the both sides S1 and S2 of the folding portion FA and portions of the folding portion FA adjacent to the both sides S1 and S2 of the folding portion FA.

When the first protective layer EPL1 and the second protective layer EPL2 are disposed on the electronic panel EP to be in contact with the electronic panel EP in the folding portion FA, a thickness in the third direction DR3 of the portions adjacent to the both sides S1 and S2 of the folding portion FA of the electronic panel EP may increase. When the thickness of the portions adjacent to the both sides S1 and S2 of the folding portion FA of the electronic panel EP increases, the rigidity of the both sides S1 and S2 of the folding portion FA may be enhanced. Thus, cracks that occur due to the stress applied to the both sides S1 and S2 of the folding portion FA may be prevented.

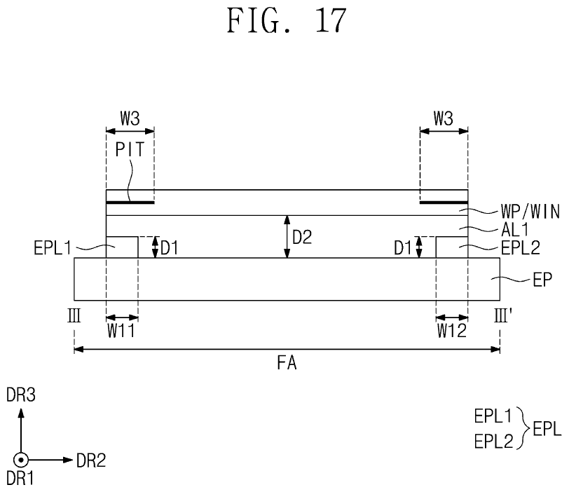

FIG. 17 is a cross-sectional view taken along a line III-III′ shown in FIG. 16.

For the convenience of explanation, components disposed under the electronic panel EP are omitted. Among components of the electronic panel EP, the first adhesive layer AL1, the window WIN, the window protective layer WP, and the print layer PIT are illustrated, and the others are omitted. In addition, the window protective layer WP and the window WIN are depicted as a single layer in the figures for simplification.

Referring to FIG. 17, the first adhesive layer AL1 may be disposed on the electronic panel EP, and the window WIN and the window protective layer WP may be disposed on the first adhesive layer AL1. The first adhesive layer AL1 may be disposed between the electronic panel EP and the window WIN.

The first protective layer EPL1 and the second protective layer EPL2 may be disposed on the electronic panel EP. The first protective layer EPL1 and the second protective layer EPL2 may be in direct contact with an upper surface of the electronic panel EP. The first protective layer EPL1 and the second protective layer EPL2 may be disposed on the electronic panel EP, and the first adhesive layer AL1 may be disposed on the first and second protective layers EPL1 and EPL2 and the electronic panel EP.

The first protective layer EPL1 and the second protective layer EPL2 may be disposed between the first adhesive layer AL1 and the electronic panel EP. When the first adhesive layer AL1 is disposed on the electronic panel EP, the first protective layer EPL1 and the second protective layer EPL2 may be in direct contact with the first adhesive layer AL1 and may be covered by the first adhesive layer AL1.

When the first adhesive layer AL1 is disposed directly on the first and second protective layers EPL1 and EPL2, the first and second protective layers EPL1 and EPL2 may be more firmly attached to the electronic panel EP by the first adhesive layer AL1.

Hereinafter, a term “thickness” may refer to a length measured in the third direction DR3.

Each of the first protective layer EPL1 and the second protective layer EPL2 may have a first thickness D1 in the third direction DR3. The first adhesive layer AL1 may have a second thickness D2 in the third direction DR3. In an embodiment, the first thickness D1 is smaller than the second thickness D2. As an example, the first thickness D1 may be within a range from about 10% to about 15% of the second thickness D2.

FIG. 17 shows the protective layers EPL1 and EPL2 opposite to each other in the second direction DR2, however, each of the protective layers EPL1 and EPL2 may be provided in plural in the third direction DR3. That is, each of the protective layers EPL1 and EPL2 may have a single-layer or multi-layer structure. The protective layers EPL1 and EPL2 may include various materials, such as metal, acryl, epoxy or siloxane. The print layer PIT may have a third width W3 in the second direction DR2. In an embodiment, the first-first width W11 and the first-second width W12 are smaller than the third width W3. The print layer PIT may prevent users from viewing portions of the protective layers EPL1 or EPL2.

The first protective layer EPL1 and the second protective layer EPL2 may be formed on the electronic panel EP. The first protective layer EPL1 and the second protective layer EPL2 may be simultaneously or substantially simultaneously formed through the same process. Then, the first adhesive layer AL1 may be formed on the electronic panel EP, the first protective layer EPL1, and the second protective layer EPL2. The window WIN and the window protective layer WP may be disposed on the first adhesive layer AL1.

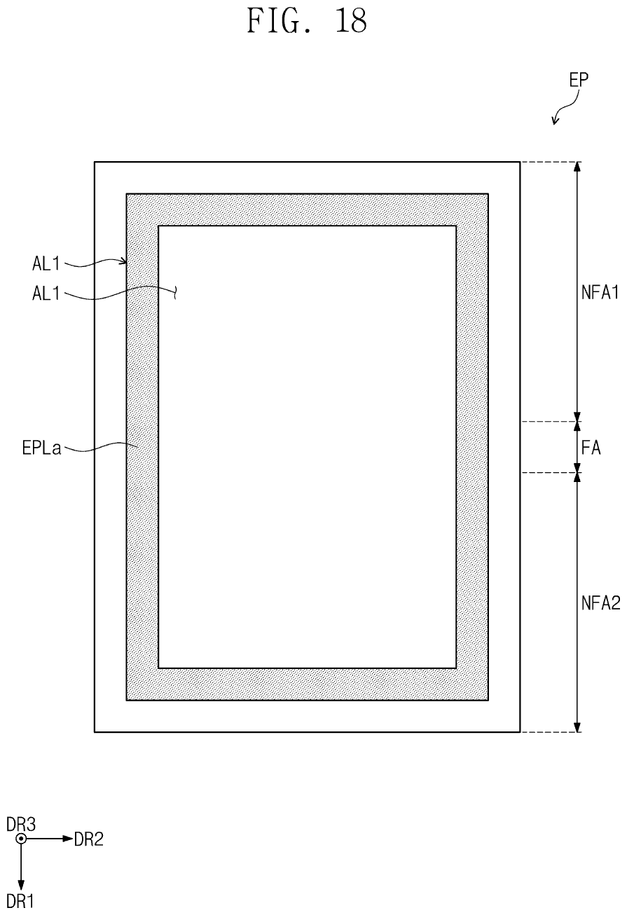

FIGS. 18 to 22 are plan views of electronic devices according to embodiments of the present disclosure.

Referring to FIGS. 16 and 18, the first protective layer EPL1 and the second protective layer EPL2 (shown in FIG. 16) may be provided integrally with each other as shown in FIG. 18. A protective layer EPLa obtained by integrally connecting the first protective layer EPL1 and the second protective layer EPL2 may extend along an edge of an electronic panel EP to form a closed-loop shape. The protective layer EPLa may be disposed in a folding portion FA, a first non-folding portion NFA1, and a second non-folding portion NFA2.

The protective layer EPLa may extend along a boundary of the first adhesive layer AL1 to form a closed-loop shape and may be disposed parallel to the edge of the electronic panel EP. Since the protective layer EPLa is disposed on the electronic panel EP along the edge of the electronic panel EP, a thickness in a portion of the electronic panel EP, which is adjacent to the edge, may increase. When the protective layer EPLa is disposed in direct contact with the electronic panel EP, the rigidity of the edge of the electronic panel EP in the folding portion FA, the first non-folding portion NFA1, and the second non-folding portion NFA2 may be enhanced. Thus, cracks caused by stress concentrated on the edge of the electronic panel EP may be prevented or reduced.

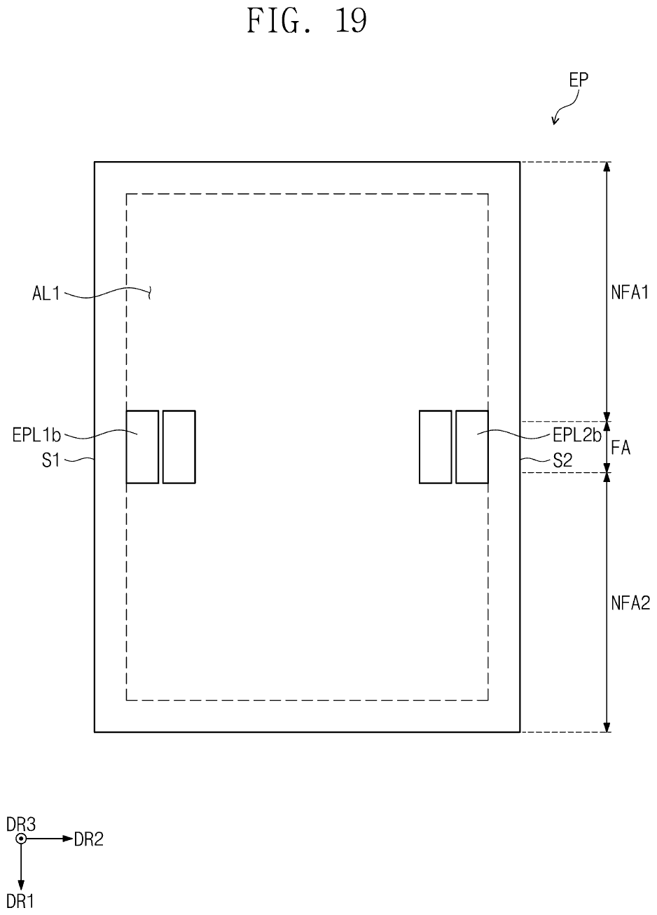

Referring to FIG. 19, a first protective layer EPL1b may be provided in plural, and a second protective layer EPL2b may be provided in plural. The first protective layers EPL1b may be arranged in the second direction DR2, and the second protective layers EPL2b may also be arranged in the second direction DR2. The first protective layers EPL1b may be spaced apart from one another in the second direction DR2. The second protective layers EPL2b may be spaced apart from one another in the second direction DR2. The first protective layers EPL1b may extend in the first direction DR1 and may be adjacent to a first side S1. The second protective layers EPL2b may extend in the first direction DR1 and may be adjacent to a second side S2. The first and second protective layers EPL1b and EPL2b may be disposed in a folding portion FA and may extend in the first direction DR1 to be disposed in a first non-folding portion NFA1 and a second non-folding portion NFA2. When each of the first protective layer EPL1b and the second protective layer EPL2 is provided in plural, a thickness of both sides S1 and S2 of the folding portion FA and a thickness of a center of the folding portion FA may increase. The rigidity of the both sides S1 and S2 of the folding portion FA and the center of the folding portion FA may be enhanced. Thus, cracks caused by stress concentrated on the both sides S1 and S2 of the folding portion FA and the center of the folding portion FA may be prevented or reduced.

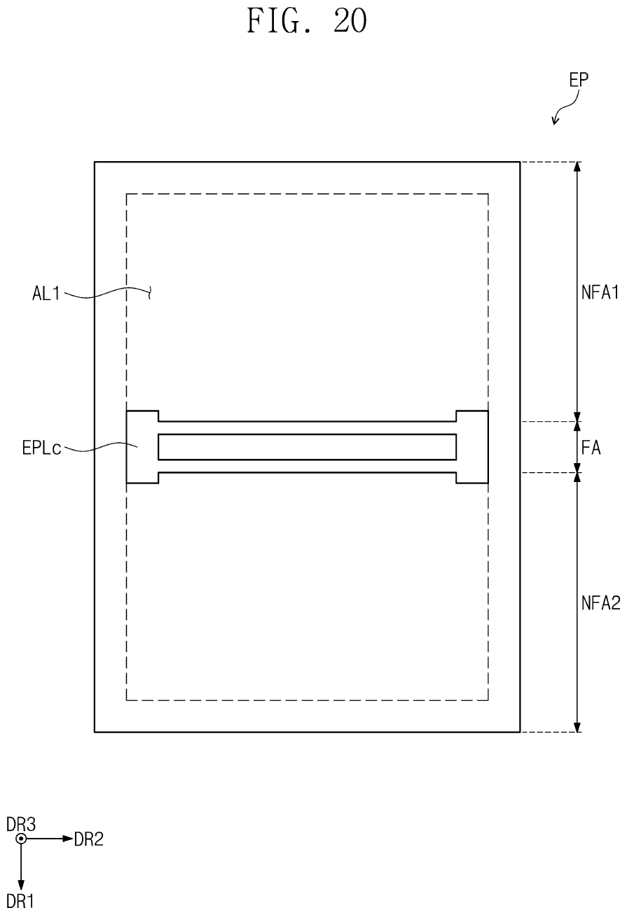

Referring to FIGS. 16 and 20, the first protective layer EPL1 and the second protective layer EPL2 (refer to FIG. 16) may be provided integrally with each other. A protective layer EPLc obtained by integrally connecting the first protective layer EPL1 and the second protective layer EPL2 (refer to FIG. 16) and provided as a single unitary form may extend along an edge of a folding portion FA. The protective layer EPLc may include a portion extending in the first direction DR1 in the folding portion FA and a portion extending in the second direction DR2 in the folding portion FA. The protective layer EPLc may extend further to a first non-folding portion NFA1 and a second non-folding portion NFA2, which are adjacent to the folding portion FA. Portions of the protective layer EPLc, which extends in the first direction DR1, may be disposed in the first non-folding portion NFA1 and the second non-folding portion NFA2, respectively. In an embodiment, the protective layer EPLc has a shape that includes a first rectangular portion adjacent a first edge of the first adhesive layer AL1, a second rectangular portion adjacent a second edge of the first adhesive layer AL1 opposite the first edge, a third rectangular portion connected to the first and second rectangular portions, and a fourth rectangular portion connected to the first and second rectangular portions and spaced apart from the third rectangular portion. The shape may have a hollow interior or an opening that may also be rectangular. All the portions may overlap the folding portion FA but the first and second rectangular portions may slightly overlap the non-folding portions NFA1 and NFA2. Due to the protective layer EPLc, a thickness of the folding portion FA may increase. Accordingly, the rigidity of the folding portion FA may be enhanced. Thus, cracks caused by stress concentrated on the folding portion FA may be prevented or reduced.

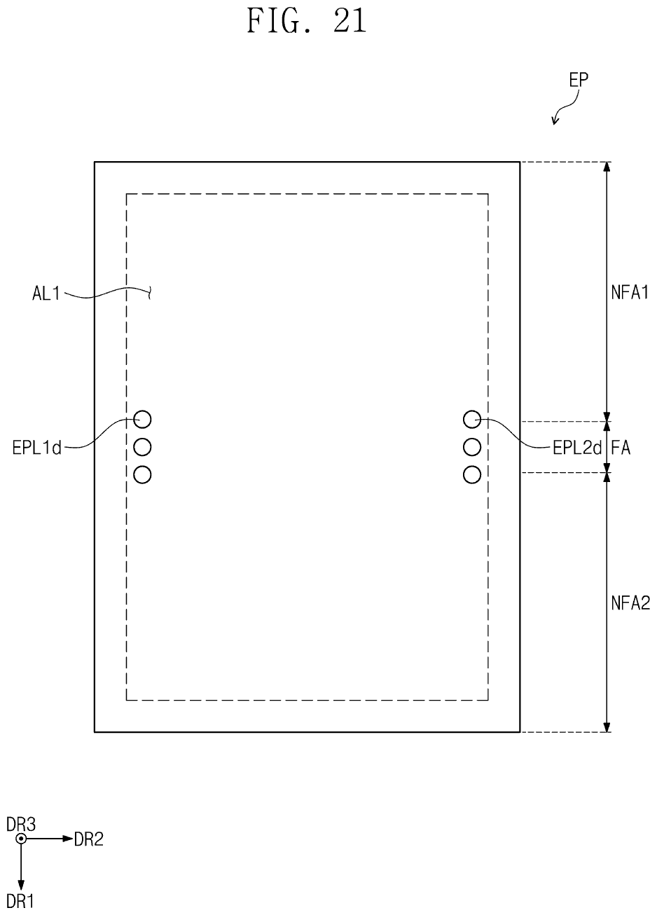

Referring to FIG. 21, first protective layers EPL1d and second protective layers EPL2d may be provided in the form of a dot (or a circle or ellipse) and may be arranged on an electronic panel EP. Each of the first protective layers EPL1d and the second protective layers EPL2d may be arranged in the first direction DR1. Since the first protective layers EPL1d and the second protective layers EPL2d are arranged in the form of a dot, a repulsive force of the first protective layers EPL1d and the second protective layers EPL2d against the electronic panel EP may be reduced when the electronic panel EP is folded. The first protective layer EPL1d and the second protective layer EPL2d should not exert influence on the folding operation of the electronic panel EP, and a thickness of portions of the electronic panel EP, which corresponds to the first protective layer EPL1d and the second protective layer EPL2d, may increase. As a result, cracks caused by stress concentrated on a folding portion FA may be prevented or reduced. For example, the dot-patterned protective layers may allow the electronic panel EP to bend more smoothly with less resistance, preventing excessive stress buildup and reducing the risk of damage during repeated folding and unfolding. The dots may be spaced apart from one another in a column as shown in FIG. 21 or slightly offset from one another.

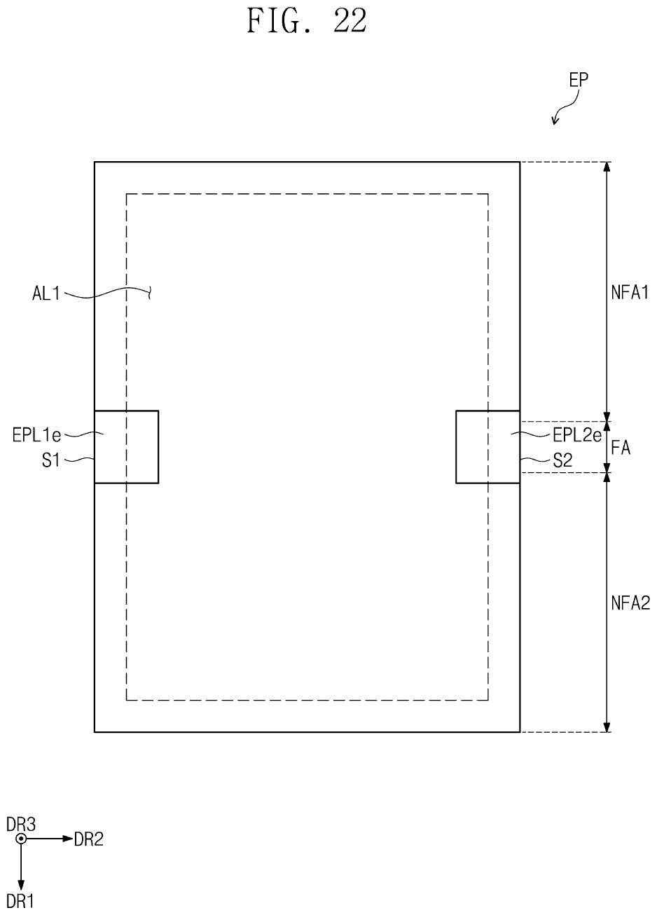

Referring to FIG. 22, when viewed in the plane, an edge of a first protective layer EPL1e facing outward may extend to a first side S1 to overlap the first side S1. When viewed in the plane, an edge of a second protective layer EPL2e facing outward may extend to a second side S2 to overlap the second side S2. For example, the protective layers EPL1e and EPL2e may extend beyond edges of the first adhesive layer AL1. When compared to the first and second protective layers EPL1 and EPL2 shown in FIG. 16, the first protective layer EPL1e and the second protective layer EPL2e extend further in the second direction DR2 and the direction opposite to the second direction DR2 and may be adjacent to the both sides S1 and S2 of a folding portion FA of the electronic panel EP. When the first protective layer EPL1e and the second protective layer EPL2e extend in the second direction DR2 and the direction opposite to the second direction DR2, areas where the first protective layer EPL1e and the second protective layer EPL2e are disposed may increase on the electronic panel EP.

When a thickness of portions adjacent to the both sides S1 and S2 of the folding portion of an electronic panel EP increases, the rigidity of the both sides S1 and S2 of the folding portion FA may be enhanced. Thus, cracks caused by stress concentrated on the both sides S1 and S2 of the folding portion FA may be prevented or reduced.

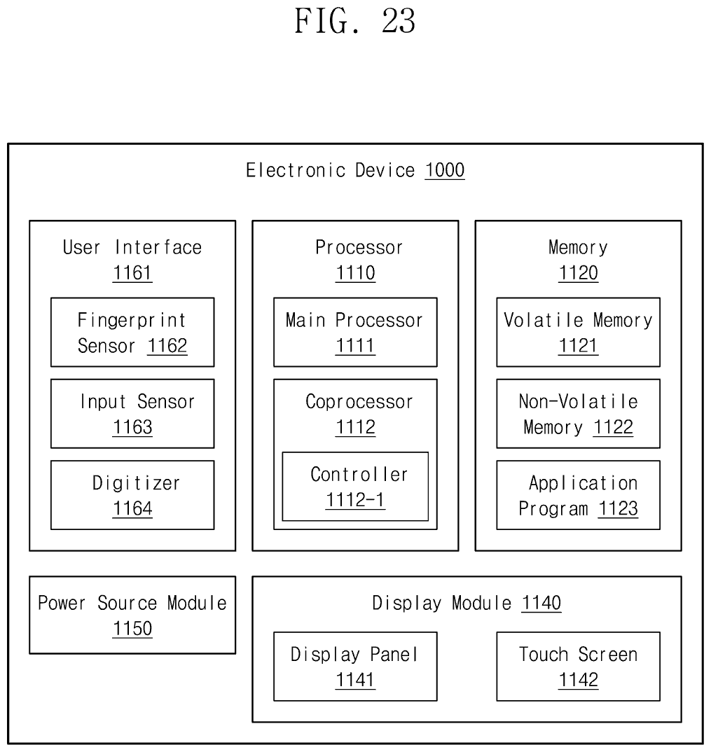

FIG. 23 is a diagram illustrating an electronic device according to an embodiment of the present invention. Referring to FIG. 23, the electronic device 1000 according to one embodiment of the present invention may output various information (e.g., images, text, music, etc.) through a display module 1140, which, for example, may correspond to the display device shown in FIGS. 1-4. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 may be an AR/VR headset.

In some embodiments, memory 1120 may store information such as software codes for operating an application program 1123. The application program 1123 may include software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module or the camera device. The processor 1110 may transmit image data corresponding to a captured image acquired through the camera module to the display module 1140. The display module 1140 may display an image corresponding to the captured image through the display panel 1141.

For example, the camera device may be configured to capture images of an alignment inspection area of the electronic device, where the alignment inspection area includes an alignment bump (e.g., ABP), an alignment pad (e.g., APD) bonded to the alignment bump, and an alignment polymer pattern (e.g., APP) that is spaced apart from the alignment pad; and the processor 1110 may be configured to: process the captured images to detect center positions of the alignment bump, the alignment pad, and the alignment polymer pattern; compare the detected center positions of the alignment bump and the alignment pad with the center position of the alignment polymer pattern; and determine presence of misalignment based on results of the compare.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

The memory 1120 may store instructions, that, when executed by the processor 1110, cause it to perform the above steps of processing, comparing, and determining misalignment.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The processor 1110 may provide an output signal to the user interface 1161 based on the determination of misalignment, where the output signal can be used to alert operators or activate further inspection or correction processes.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIGS. 1-4.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIGS. 1-4.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

Although various embodiments of the present disclosure have been described, it is to be understood that the present disclosure is not limited to these embodiments since various changes and modifications can be made by one ordinary skilled in the art within the spirit and scope of the present disclosure as hereinafter claimed. Therefore, the disclosed subject matter should not be limited to any single embodiment described herein.

What is claimed is:

1. A display device comprising:
an electronic panel comprising a folding portion and a non-folding portion arranged in a first direction, the folding portion comprising a first side and a second side opposite to the first side in a second direction intersecting the first direction;
a window disposed on the electronic panel;
an adhesive layer disposed between the electronic panel and the window; and
a first protective layer disposed between the adhesive layer and the electronic panel, wherein the first protective layer is adjacent to the first side of the folding portion.

2. The display device of claim 1, further comprising a second protective layer spaced apart from the first protective layer in the second direction and disposed adjacent to the second side between the adhesive layer and the electronic panel.

3. The display device of claim 2, wherein the first protective layer and the second protective layer extend in the first direction.

4. The display device of claim 2, wherein an edge of the first protective layer, which faces outward, is spaced apart from the first side, and an edge of the second protective layer, which faces outward, is spaced apart from the second side when viewed in a plane.

5. The display device of claim 4, wherein the edge of the first protective layer, which faces outward, and the edge of the second protective layer, which faces outwards, respectively overlap both sides of the adhesive layer, which are opposite to each other in the second direction, when viewed in the plane.

6. The display device of claim 2, wherein the first protective layer and the second protective layer extend to the non-folding portion adjacent to the folding portion.

7. The display device of claim 2, wherein a width of the first protective layer in the second direction and a width of the second protective layer in the second direction are each within a range from about 10% to about 15% of a width of the electronic panel in the second direction.

8. The display device of claim 2, wherein each of the first protective layer and the second protective layer has a first thickness smaller than a second thickness of the adhesive layer in a third direction perpendicular to a plane defined by the first direction and the second direction.

9. The display device of claim 8, wherein the first thickness is within a range from about 10% to about 15% of the second thickness.

10. The display device of claim 2, wherein the first protective layer and the second protective layer are in direct contact with the adhesive layer and covered by the adhesive layer.

11. The display device of claim 2, wherein the first protective layer and the second protective layer are in direct contact with an upper surface of the electronic panel.

12. The display device of claim 2, wherein an edge of the first protective layer, which faces outward, extends to the first side and overlaps the first side, and an edge of the second protective layer, which faces outward, extends to the second side and overlaps the second side when viewed in a plane.

13. The display device of claim 2, wherein the first protective layer and the second protective layer are integrally connected and extend along an edge of the electronic panel in a closed-loop shape.

14. The display device of claim 2, wherein the first protective layer includes a plurality of first protective layers that extend in the first direction and are adjacent to the first side, the second protective layer includes a plurality of second protective layers that extend in the first direction and are adjacent to the second side.

15. The display device of claim 2, wherein the first protective layer and the second protective layer are integrally connected, extend along an edge of the folding portion, and further extend to a portion of the non-folding portion adjacent to the folding portion.

16. The display device of claim 2, wherein each of the first protective layer and the second protective layer are arranged as multiple dots on the electronic panel.

17. A display device comprising:
an electronic panel comprising a folding portion and a non-folding portion arranged in a first direction;
a window disposed on the electronic panel;
an adhesive layer disposed between the electronic panel and the window;
a first protective layer adjacent to a first side of the folding portion; and
a second protective layer adjacent to a second side of the folding portion opposite to the first side in a second direction intersecting the first direction,
wherein the first and second protective layers extend in the first direction and overlap opposite edges of the adhesive layer in the second direction.

18. The display device of claim 17, wherein each of the protective layers has a thickness smaller than a thickness of the adhesive layer in a third direction perpendicular to a plane defined by the first direction and the second direction.

19. The display device of claim 17, wherein each of edges of the protective layers, which faces outward, extends to the first side to overlap the first side and extends to the second side to overlap the second side.

20. An electronic device comprising:
a display device including a first hole to transmit an optical signal;
an electro-optical module disposed under the display device and overlapping the first hole for receiving the optical signal; and
first and second cases accommodating the display device and the electro-optical module and enabling the display device to be folded, the display device comprising:
an electronic panel comprising a folding portion and a non-folding portion arranged in a first direction, the folding portion comprising a first side and a second side opposite to the first side in a second direction intersecting the first direction;
a window disposed on the electronic panel;
an adhesive layer disposed between the electronic panel and the window; and
a first protective layer disposed between the adhesive layer and the electronic panel,
wherein the first protective layer is adjacent to the first side of the folding portion.
